(19) United States
(12) Patent Application Publication
(10) Pub. No.: US 2017/0278730 A1
(43) Pub. Date: Sep. 28, 2017

(54) PLASMA PROCESSING APPARATUS AND PLASMA PROCESSING METHOD

(71) Applicant: Hitachi High-Technologies Corporation, Tokyo (JP)

(72) Inventors: Takumi TANDOU, Tokyo (JP); Kenetsu YOKOGAWA, Tokyo (JP)

(21) Appl. No.: 15/469,684

(22) Filed: Mar. 27, 2017

(30) Foreign Application Priority Data
Mar. 28, 2016 (JP) 2016-062978
Dec. 14, 2016 (JP) 2016-241887

(51) Int. Cl. H01L 21/67; H01J 37/32; H01L 21/683

(52) U.S. Cl. CPC H01L 21/67069; H01L 21/67248; H01L 21/6833; H01J 37/32192; H01J 37/32541; H01J 2237/334

(57) ABSTRACT

A plasma processing apparatus including a sample stage arranged in a processing chamber, a temperature regulator arranged in an interior of the sample stage, a film made of a dielectric that configures the upper surface of the sample stage, and including a film-like electrode therein, a protruding portion arranged on an upper surface of the film made of a dielectric on an outer periphery-side area, and arranged to surround a center-side area of the upper surface in a ring manner, a power source that supplies power for forming electrostatic force that absorbs a wafer arranged above the electrode in the film made of a dielectric, and a controller that regulates the power from the power source and the gas introduction between the wafer and the film to hold the wafer above the film in a noncontact manner.

### CLAIM OF PRIORITY

This application claims priority from Japanese Patent Application No. 2016-062978 filed on Mar. 28, 2016 and Application No. 2016-241887 filed on Dec. 14, 2016, the entire contents of which are hereby incorporated by reference into this application.

### BACKGROUND OF THE INVENTION

1. Field of the Invention

The present invention relates to a plasma processing apparatus and a plasma processing method, and especially relates to a plasma processing apparatus and a plasma processing method that are favorable to hold a sample on a sample stage in a noncontact manner.

2. Description of the Related Art

Continuous processing of a wafer at different processing temperatures is required corresponding to a semiconductor device manufacturing method. Such processing has a problem that a back surface of the wafer and an electrostatic chuck that holds the wafer are rubbed due to a thermal expansion difference between the wafer and the electrostatic chuck and particles occur. As a technology for solving such a problem, a technology disclosed in JP 2015-8249 A is known. JP 2015-8249 A discloses the technology to effectively suppress the occurrence of particles by a temperature control method including a temperature-fall control process of controlling the temperature of the electrostatic chuck to a second temperature lower than a first temperature in stages, after executing plasma processing of a body to be processed in a processing chamber in a state where the temperature-regulatable electrostatic chuck is controlled to the first temperature, and a purging process of purging the processing chamber with an inert gas. According to the disclosed technology, the thermal expansion difference during the temperature-fall control is suppressed and the occurrence of particles is effectively suppressed. Further, the occurring particles are immediately exhausted from the chamber to an outside, and the number of the particles can be decreased, by performing the temperature-fall control process and the purging process in parallel.

The technology disclosed in JP 2015-8249 A is effective to prevent the particles from flying to a surface of the wafer, the particles having occurred in the back surface of the wafer and being a cause of foreign substances. However, the present conventional technology cannot prevent the occurrence of the particles itself in the back surface of the wafer. Therefore, the particles adhering to the back surface of the wafer scatter around and adhere to a wafer conveying path when the wafer is carried out from the processing chamber to an outside, and the particles may adhere to another wafer, become the foreign substances, and contaminate the another wafer, when the another wafer is conveyed.

Further, such a conventional technology cannot prevent change over time of the shape of a surface of a member that configures a wafer placing surface of the sample stage and its heat transfer characteristics due to wear by sliding of the surface of the member against the wafer. Therefore, the conventional technology has a problem that a decrease in a yield due to change over time cannot be suppressed. To solve the problem, it is necessary to further suppress rubbing and sliding due to the thermal expansion difference caused among the wafer, the member that configures the wafer placing surface of the sample stage on which the wafer is placed, and the back surface of the wafer.

As means therefor, (1) a sample and the member that configures the placing surface of the sample stage are made of the same material, or (2) the heat is transferred between the sample and the upper surface of the sample stage while the sample is held above the upper surface of the sample stage in a noncontact manner can be considered. Meanwhile, if silicon or its compound that is a typical material that configures the sample such as a semiconductor wafer is employed as the material of the member that configures the upper surface of the sample stage, resistance to plasma is lower than ceramics that have been used in the conventional technologies, and thus maintenance of the sample stage placing surface needs to be rather conducted in a shorter period in a device using such a material, and performance cannot be exhibited in a long period of time. Further, the frequency and the time of maintenance work are increased, and efficiency of the entire processing by the device is decreased.

Therefore, a configuration that enables heat transfer in a noncontact state between the electrostatic chuck and the wafer in a plasma processing apparatus like (2) is desired. As a technology to hold the wafer in a noncontact manner in this way, a technology described in JP 8-264626 A is known.

JP 8-264626 A discloses a sample holding device including a sample holding surface that holds a sample to be held in a noncontact manner, using Bernoulli effect caused by causing a fluid to flow between the sample and the sample holding surface facing the sample, the sample holding surface has a configuration in which a size of an area surrounded by a boundary formed on the sample holding surface, in which magnitude of tension acting between an outer peripheral edge of the held sample and the sample holding surface is drastically changed, becomes nearly the same as a size of the sample in a direction into which position shift of the sample with respect to the sample holding surface should be suppressed.

Further, JP 8-264626 A discloses, in a case where the fluid is a gas, the sample holding surface as a holding tool being charged by the gas flowing to cause Bernoulli effect, and the sample being charged by electrical effect, thereby to obtain suppression force to suppress the position shift in a lateral direction of the held sample, and an electrode or the like being arranged on the sample holding surface as a holding tool, and the holding tool and the sample being more initiatively charged, thereby to realize more stable noncontact holding.

### SUMMARY OF THE INVENTION

However, the above-described technologies have insufficient consideration about the following points, and thus have problems.

JP 2015-8249 A cannot prevent the occurrence of the particles itself in the back surface of the wafer, and thus the particles may adhere to and contaminate another wafer, as described above. Further, JP 2015-8249 A cannot prevent the shape of the surface of the member and its heat transfer properties due to sliding and wearing of the surface of the member that configures the wafer placing surface of the sample stage with the wafer being changed over time, and thus has a problem that a decrease in the yield changed over time cannot be suppressed.

Further, JP 8-264626 A does not sufficiently consider application to a plasma processing apparatus that processes the sample under decompression using plasma, and has a problem that efficient processing cannot be performed. That is, to exhibit Bernoulli effect by the gas supplied to the back surface of the wafer, there is a problem that a larger amount of gasses is required than the gas amount used in the plasma processing, and the large amount of the gasses influences on the plasma processing under decompression.

For example, in the plasma processing under decompression like 1 Pa, the gas of 300 SCCM as a flow rate of a processing gas is supplied and is made into plasma. Under such a processing condition, if the amount of flowout of the gas, which floats the wafer, from the back surface of the wafer, is large, there is a problem that a large-capacity vacuum exhaust device is required to maintain a predetermined decompressed atmosphere, and the device is increased in size. Further, there is a problem that the gas flowing out from the back surface of the wafer is diffused in a processing chamber where the plasma is generated and influences a plasma state of the processing gas, and a predetermined processing result may not be able to be obtained. Therefore, in the above conventional technology, the yield of the processing of a substrate-like sample such as a semiconductor wafer is decreased, and efficiency of vacuum processing of the sample is decreased.

An objective of the present invention is to provide a plasma processing apparatus and a plasma processing method that can improve the yield of processing and improve efficiency of the processing.

The above objective is achieved by including a sample stage for installing a sample to be processed, in a plasma processing apparatus, a surface of the sample stage includes an electrostatic absorbing film obtained by coating a conductor with an insulating body, at least three heat transfer gas supply passages, a ring-like protruding portion included on the surface of the sample stage on an outer peripheral side with respect to the heat transfer gas supply passage, and an insulating body that restricts a moving range in a radial direction, of the sample to be processed, installed in an outer peripheral portion of the sample to be processed, and controlling electrostatic absorbing force and supply pressure of a heat transfer gas, to regulate the temperature of the sample to be processed while holding a back surface of the sample to be processed and the sample stage surface in a noncontact state.

Further, the above objective is achieved by including a sample stage for installing a sample to be processed, in a plasma processing apparatus, a surface of the sample stage includes an electrostatic absorbing film obtained by coating a conductor with an insulating body, at least three heat transfer gas supply passages, a ring-like protruding portion included on the surface of the sample stage on an outer peripheral side with respect to the heat transfer gas supply passage, and an insulating body that restricts a moving range in a radial direction, of the sample to be processed, installed in an outer peripheral portion of the sample to be processed, and controlling electrostatic absorbing force and supply pressure of a heat transfer gas, while holding a back surface of the sample to be processed and the sample stage surface in a noncontact state, and performing plasma processing while rotating the sample to be processed.

According to the present invention, the wafer can be fixed above the upper surface of the sample stage in a noncontact state, by balancing electrostatic absorbing force by an electrostatic chuck and floating force by the heat transfer gas. Accordingly, rubbing between the wafer and the sample stage surface when the sample stage is temperature-controlled can be prevented, and occurrence of foreign substances due to wear and change over time of heat transfer performance can be suppressed.

Further, according to the configuration of the present invention, the sample stage surface becomes an insulating body having resistance to plasma. Therefore, the electrode for electrostatic absorption is not directly exposed to the plasma, and change over time of the electrostatic absorbing force and heavy metal pollution in the processing chamber by the electrode material can be prevented. Further, the ring-like protrusion is installed in an outer periphery of the sample stage surface, whereby the heat transfer gas pressure on the back surface side of the wafer is made uniform in the plane, and a temperature profile of the sample stage surface can be directly reflected on the wafer.

Further, in a noncontact fixed state, the heat transfer gas flowing in the gap between the back surface of the wafer and the sample stage surface is brought to flow in a circumferential direction, thereby to rotate the wafer. Accordingly, processing uniformity in the peripheral direction during the plasma processing can be improved.

### BRIEF DESCRIPTION OF THE DRAWINGS

FIG. 1 is a vertical sectional view illustrating an outline of a configuration of a plasma processing apparatus according to a first embodiment of the present invention;

FIG. 2A is a vertical sectional view illustrating an outline of a configuration of a sample stage of the apparatus illustrated in FIG. 1, and FIG. 2B is a plan view of FIG. 2A as viewed from an arrow view A;

FIG. 3 is a time chart illustrating a flow of a time chart illustrating a flow of an operation of processing performed by the apparatus illustrated in FIG. 1;

FIG. 4 is a time chart illustrating a flow of a time chart illustrating a flow of an operation of another processing performed by the apparatus illustrated in FIG.

1;

FIG. 5 is a time chart illustrating a flow of a time chart illustrating a flow of an operation of still another processing performed by the apparatus illustrated in FIG. 1;

FIG. 6A is a vertical sectional view schematically illustrating electrostatic absorbing force formed in the sample stage to be applied to the processing of FIGS. 3 and 4, and FIG. 6B is a vertical sectional view schematically illustrating electrostatic absorbing force formed in the sample stage to be applied to the processing of FIG. 5;

FIG. 7 is a vertical sectional view illustrating an outline of a configuration of another example of the sample stage of FIGS. 2A and 2B;

FIG. 8A is a plan view illustrating an outline of a configuration of a sample stage of a plasma processing apparatus according to a second embodiment of the present invention, and FIG. 8B is a partial vertical sectional view of FIG. 8A as viewed from an arrow view B-B;

FIG. 9A is a plan view illustrating an outline of a configuration of another example of the sample stage illustrated in FIGS. 8A and 8B, and FIG. 9B is a partial vertical sectional view of FIG. 9A as viewed from an arrow view C-C;

FIG. 10 is a vertical sectional view illustrating an outline of a configuration of a sample stage of a plasma processing apparatus according to a third embodiment of the present invention;

FIG. 11A is a vertical sectional view illustrating an outline of a configuration of an electrostatic absorbing layer of the sample stage of FIG. 10, and FIG. 11B is a vertical sectional view illustrating another example of FIG. 11A;

FIG. 12A is a plan view with omission of the left half, of the sample stage of FIG. 10, as viewed from an arrow view D, and FIG. 12B is a plan view with omission of the left half, illustrating another example of FIG. 12A;

FIGS. 13A and 13B are plan views illustrating rotation of a wafer W by the sample stage of FIG. 10, and FIG. 13C is a diagram schematically illustrating an example of rotation of the wafer W and change of pressure detected with the rotation;

FIG. 14A is a vertical sectional view illustrating an outline of a configuration of a sample stage illustrating a comparative example of a third embodiment of the present invention, corresponding to the sample stage of FIG. 10, and FIG. 14B is a plan view of FIG. 14A as viewed from an arrow view E;

FIGS. 15A and 15B are side views schematically illustrating an outline of a sample holder according to an embodiment of a sample conveyor of the present invention;

FIGS. 16A to 16C are diagrams schematically illustrating an operation to convey a wafer between the sample stage that holds the wafer in a noncontact manner, of the embodiments illustrated in FIGS. 1 to 10, the sample conveyor of the embodiment illustrated in FIGS. 15A and 15B;

FIGS. 17A to 17C are diagrams schematically illustrating an outline of an operation to apply plasma processing to a surface and a back surface of the wafer, using the plasma processing apparatus according to the embodiment illustrated in FIGS. 15A and 15B; and

FIGS. 18A and 18B are diagrams schematically illustrating an example of performing processing using plasma for both the surface and the back surface of the wafer W, using the sample conveyor 104 and the sample stage 101 described in FIGS. 15A and 15C to 17A to 17C.

### DESCRIPTION OF THE PREFERRED EMBODIMENTS

The present invention electrostatically absorbs and holds, in processing a sample by changing a temperature of the sample in a vacuum processing chamber, the sample on a sample stage having an electrostatic chuck, then supplies a high-pressure heat transfer gas between the sample stage and a back surface of the sample to float the sample, balances floating force that acts on the sample by a gas pressure of the heat transfer gas and electrostatic absorbing force that acts on the sample by the electrostatic chuck, maintains a gap between the sample stage and the floated sample to a heat-transferable gap by the heat transfer gas and holds the sample in a noncontact manner, changes the temperature of the sample to a predetermined temperature while remaining holding the sample in a noncontact manner, suppresses flowout of the heat transfer gas from an outer periphery of the back surface of the sample to prevent an influence of the sample on the processing, thereby to enable the processing of the sample.

Further, the present invention causes the flow of the heat transfer gas on the back surface of the sample to have a component in a peripheral direction and rotates and holds the sample in a noncontact manner, thereby to improve uniformity of the processing of the sample.

Further, the present invention discharges a small amount of the heat transfer gas, which flows out to the outer periphery of the back surface of the sample, from an outer peripheral portion of the sample stage without allowing the gas to flowout into the vacuum processing chamber, to prevent an influence on the sample processing under decompression.

Hereinafter, embodiments of the present invention will be described using the drawings.

### First Embodiment

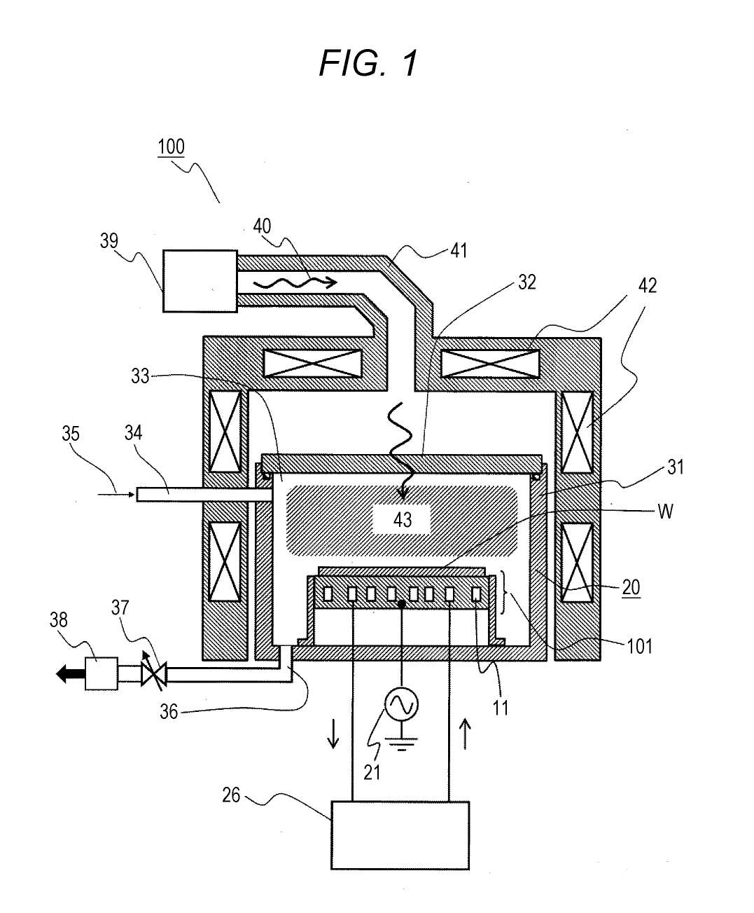

A first embodiment of the present invention will be described using FIGS. 1 to 4.

FIG. 1 is a vertical sectional view illustrating a schematic configuration of an effective magnetic field microwave plasma processing apparatus as a plasma processing apparatus according to an embodiment of the present invention.

In FIG. 1, a plasma processing apparatus 100 includes a vacuum vessel 20 including a processing chamber 33 decompressed to have a predetermined degree of vacuum suitable for the processing therein, a plasma forming unit arranged above and around sides of the vacuum vessel 20, and which forms and supplies an electric field or a magnetic field for forming plasma to the processing chamber 33, and an exhaust unit arranged below the vacuum vessel 20, communicating with an interior of the processing chamber 33 through an exhaust port 36 in a lower portion of the processing chamber 33, and including a vacuum pump such as a turbo molecular pump 38. The vacuum vessel 20 includes a processing chamber wall 31 made of metal, having a cylindrical shape, and arranged to surround an outer periphery of the processing chamber 33, and a disk-shaped lid member 32 made of a dielectric that can transmit microwaves, such as quartz glass, and placed on an upper end portion of a circular shape of the processing chamber wall 31.

A sealing member such as an O ring is sandwiched between a lower surface of an outer peripheral edge portion of the lid member 32 and an upper end portion of the processing chamber wall 31 to air-tightly seal the interior of the processing chamber 33. A sample stage 101 having a circular upper surface on which a substrate such as a semiconductor wafer (hereinafter, wafer W) as a sample to be processed is arranged is arranged in a lower portion of an inside of the processing chamber 33. A gas introduction pipe 34 through which a processing gas 35 for performing etching processing is introduced into the interior of the processing chamber 33 is connected to an upper portion of the processing chamber 33.

An exhaust port 36 is arranged in a bottom surface below the sample stage 101 of the processing chamber 33. The exhaust port 36 configures the exhaust unit by an exhaust pipeline through a pressure regulation valve 37. In this case, the exhaust port 36 communicates with the turbo molecular pump 38.

A flow rate or a speed of exhaust of the processing chamber 33 is regulated with the pressure regulation valve 37, and the pressure in the processing chamber 33 is regulated to a value within a predetermined range. In the present embodiment, the pressure in the processing chamber 33 is regulated to a predetermined value within a range from several Pa to several tens of Pa.

A waveguide 41 and a microwave oscillator 39 such as a magnetron arranged in an end portion of the waveguide 41, which configure the plasma forming unit, are provided above the processing chamber 33. A microwave 40 oscillated from the microwave oscillator 39 is propagated in the waveguide 41, converted into a mode of a predetermined electric field in an enlarged waveguide portion in a lower end portion of the waveguide 41, transmitted the lid member 32, and introduced into the processing chamber 33.

Solenoid coils 42 arranged to surround the vacuum vessel 20 and the enlarged waveguide portion of the waveguide 41 are provided at an outer periphery-side and above the vacuum vessel 20, to form a magnetic field in a coil axis direction in the processing chamber 33. The processing gas 35 introduced into the processing chamber 33 is excited by an interaction of the electric field of the microwave 40 and the magnetic field by the solenoid coils 42 to generate plasma 43.

High-frequency power having a predetermined frequency, which is output from a high-frequency power source 21, is supplied to the sample stage 101, a bias potential is generated in the wafer W arranged on the sample stage 101, charged particles in the plasma 43 are attracted by the bias potential, and etching processing of the wafer W is performed.

In the present embodiment, to realize a predetermined wafer temperature suitable for the processing of the wafer W, a configuration to regulate the temperature of the sample stage 101 is provided. The sample stage 101 includes an electrode block as a member made of metal and having a cylindrical shape, and a refrigerant flow channel 11 in which a refrigerant is circulated is arranged in an interior of the sample stage 101. A temperature control unit 26 such as a chiller arranged outside the vacuum vessel 20 and having a function to regulate the temperature of the refrigerant to a value within a set range is connected to the refrigerant flow channel 11 through a pipeline, and configures a circuit of the refrigerant.

In this configuration, the refrigerant supplied to the refrigerant flow channel 11 exchanges heat with the electrode block thermally connected with the wafer W to regulate the temperature of the electrode block or the wafer W to be a value within a desired range.

When the etching processing having reached an end point is detected by a detector (not illustrated) using a known technology such as an analysis of light emission of the plasma 43, the supply of the high-frequency power from the high-frequency power source 21 and the supply of the electric field and the magnetic field are stopped, the plasma 43 is put out, and the etching processing is stopped. After that, the wafer W is carried out from the processing chamber 33, a gas is supplied into the processing chamber 33 to form plasma for removing substances adhering to a member surface in the processing chamber 33, and a process to wash the processing chamber 33 is performed.

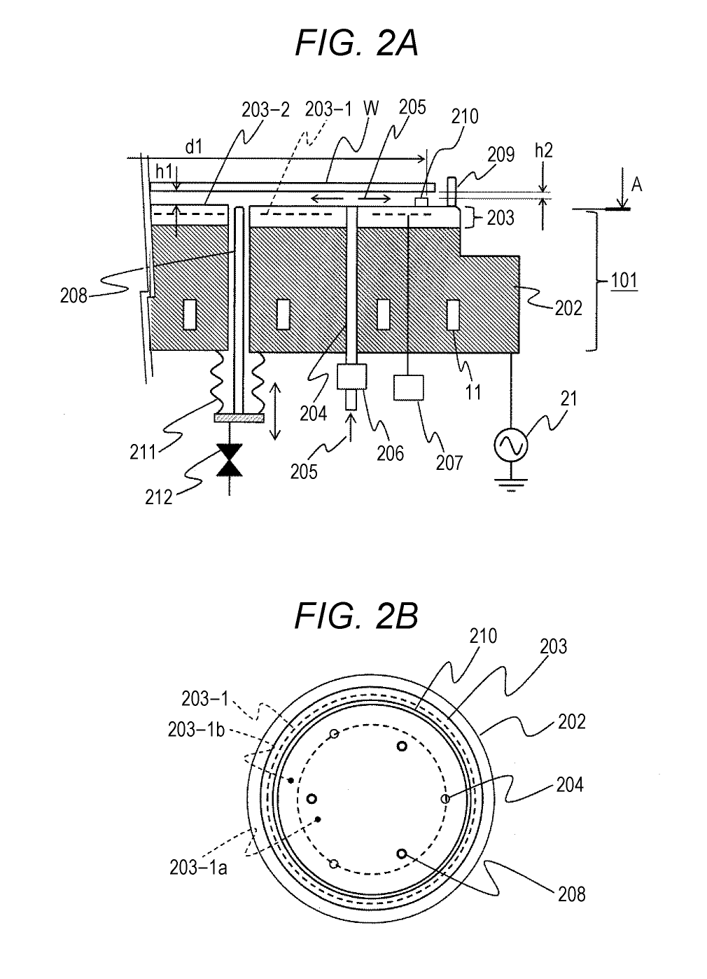

FIGS. 2A and 2B are diagrams illustrating an outline of a configuration of the sample stage included in the plasma processing apparatus according to the embodiment illustrated in FIG. 1. FIG. 2A is a vertical sectional view of the sample stage 101, and FIG. 2B is a plan view illustrating a wafer placing surface of the sample stage 101 when FIG. 2A is viewed from an arrow view A.

In FIGS. 2A and 2B, the sample stage 101 includes an electrode block 202 made of metal, which is a member having a disk shape or a cylindrical shape, and an electrostatic absorbing layer 203 that configures an electrostatic chuck arranged to cover and joined with an upper surface of the electrode block 202. The electrode block 202 includes a circular flat high-center protruding portion, which is slightly larger than the wafer W, and having a ring-like step portion formed in an upper outer periphery, the step portion being one step lower than the high-center protruding portion. A refrigerant flow channel 11 in which a heat exchange medium (hereinafter, refrigerant) having a temperature regulated within a predetermined range is circulated is arranged in a lower interior of the high-center protruding portion.

Although not illustrated in FIGS. 2A and 2B, in the sample stage 101, a cover ring made of a ceramic of quarts, alumina, or yttria is arranged to cover an upper surface or a side surface of the step portion in an upper outer peripheral edge of the electrode block 202. This covering suppress scraping of the electrode block 202 formed in the processing chamber 33 due to an interaction with the plasma 43, and adhesion of a product to the electrode block 202.

The electrostatic absorbing layer (electrostatic chuck) 203 is provided on the high-center protruding portion of the electrode block 202. The electrostatic absorbing layer 203 includes an inner electrode 203-1 as a film-like member made of a conductor, and a film-like insulating body 203-2 that covers the entire inner electrode 203-1. Tungsten is used as the material of the inner electrode 203-1, and an alumina ceramic or a ceramic of yttria having resistance to plasma is used as the material of the insulating body 203-2.

Power is supplied from a direct current power source 207 arranged outside the sample stage 101 and electrically connected with the sample stage 101 to the inner electrode 203-1 arranged in the electrostatic absorbing layer 203. A polarized charge arises in the insulating body 203-2 between the inner electrode 203-1 and the wafer W by a voltage formed by the power, and electrostatic force is generated between the electrostatic absorbing layer 203 and the wafer W, accordingly, and force to absorb the wafer W acts on an upper surface of the electrostatic absorbing layer 203.

An outer diameter of the inner electrode 203-1 is set to the same value as an outer diameter of the wafer W or to an approximated value that can be regarded as the same value. The inner electrode 203-1 is configured from a plurality of film-like electrodes, in this case, outside and inside two electrodes illustrated by the broken lines of FIG. 2B. The inner electrode 203-1 includes a film-like inside inner electrode 203-1a having a circular shape, arranged in a central area inside the wafer placing surface of the electrostatic absorbing layer 203, and to which one polarity is provided by the voltage, and an outside inner electrode 203-1b as a ring-like film-like electrode surrounding the inside inner electrode 203-1a and insulated from the inside inner electrode 203-1a, and to which a polarity different from that of the inside inner electrode 203-1a is provided.

That is, the inner electrode 203-1 configures so-called a bipolar electrostatic absorbing electrode, and the different polarities are provided to the inside and outside electrodes. Accordingly, charges of different polarities in a radial direction in the wafer W are formed in a polarized state in the surface of the inner electrode 203-1. Even in a state where the plasma 43 is not formed in the processing chamber 33, the electrostatic force that absorbs or supports the wafer W above the electrostatic absorbing layer 203 can be formed.

Note that the plane shape of the inner electrode 203-1 is not limited to the circular and ring shape illustrated in FIG. 2B, and may be a shape in which electrodes to which different polarities are provided are adjacent to each other or may be a shape such as a plurality of fan shapes including comb-teeth-shapes and semicircular shapes. Further, the inside and outside inner electrodes 203-1a and 203-1b may be divided into a plurality of electrodes in the radial direction or the peripheral direction.

Further, the electrostatic absorbing layer 203 may be formed in such a manner that layers of the insulating body 203-2 and the inner electrode 203-1 are formed by a plasma spraying method or the like to cover the upper surface of the electrode block 202, or may be formed of a sintered plate obtained by forming, in a film manner, a material such as a ceramic including a film made of metal that configures the inner electrode 203-1 therein, and then sintering and molding the film-like material in a plate manner. The electrode block 202 and the electrostatic absorbing layer 203 are joined to configure the sample stage 101 as an integral member, by a process of spraying and depositing particles in a film manner in the former case, or with an adhesive arranged between the sintered plate, and the upper surface of the electrode block 202 or a member arranged on the electrode block 202 in the latter case.

Further, a sealing portion 210 made of at least one ring-like protruding portion having an outer diameter d1 set to be slightly smaller than the outer diameter of the wafer W, and concentrically arranged with the sample stage 101 corresponding to an outer peripheral portion of the wafer W, is provided on the upper surface of the electrostatic absorbing layer 203. The outer diameter d1 of the sealing portion 210 is set to be smaller than the diameter of the wafer W, in other words, the sealing portion 210 is positioned inside the wafer W, whereby an upper surface of the sealing portion 210 can be protected from the plasma. The height of the sealing portion 210 is about several μm to several tens of μm, for example, which is slightly higher than the upper surface of the electrostatic absorbing layer 203. Accordingly, when the wafer W is electrostatically absorbed on the electrostatic absorbing layer 203, a gap is easily formed between the electrostatic absorbing layer 203 inside the sealing portion 210 and a back surface of the wafer W, especially between the electrostatic absorbing layer 203 close to the sealing portion 210 and the back surface of the wafer W. Further, partial protruding portions having the same height as the sealing portion 210 are provided in a plurality of places on the upper surface of the electrostatic absorbing layer 203 inside the sealing portion 210, thereby to form a gap entirely inside the sealing portion 210.

Openings of three or more heat transfer gas supply passages 204 and openings of three lift pins 208 arranged in the sample stage 101, penetrating the electrostatic absorbing layer 203 and the electrode block 202, are arranged on circumferences with respective radiuses, in the inside upper surface of the electrostatic absorbing layer 203 surrounded by the sealing portion 210.

A heat transfer gas 205 having heat transfer properties, such as He, is supplied to the gap between the back surface of the wafer W and the electrostatic absorbing layer 203 through the heat transfer gas supply passages 204 in a state where the wafer W is electrostatically absorbed on the upper surface of the electrostatic absorbing layer 203.

Supply of the heat transfer gas 205 to and existence of the heat transfer gas 205 between the back surface of the wafer W and the electrostatic absorbing layer 203 facilitates heat transfer between the wafer W, and the sample stage 101, the electrode block 202, or the refrigerant flowing in the refrigerant flow channel 11 inside the electrode block 202, even inside the processing chamber 33 set to a predetermined degree of vacuum, and easily makes the temperature of the wafer W be a value within a desired range. The flow rate or the speed of the heat transfer gas 205 to be supplied to the gap is regulated by an operation of a flow rate control valve 206 arranged on the heat transfer gas supply passage 204, using an output from a flowmeter (illustration is omitted) that detects the flow rate of the heat transfer gas.

Further, in the present embodiment, the lift pins 208 are respectively accommodated in three through holes arranged in a center side of the electrode block 202 and penetrating the sample stage 101. The opening of the through hole in which the lift pin 208 is arranged is surrounded by flexible wiring 211 including bellows that expands and contracts in an up and down direction, and an inside of the flexible wiring 211 and the through hole is air-tightly sealed with a sealing member such as an O ring arranged in the place in a lower portion of the sample stage 101. Note that a space below the sample stage 101 illustrated in FIG. 1, that is, a lower portion of the sample stage 101 of FIG. 2A is isolated from an atmosphere of the processing chamber 33, and is an atmosphere of an atmospheric pressure, or an equivalent pressure that can be regarded as the atmospheric pressure.

The heat transfer gas 205 is supplied to above the electrostatic absorbing layer 203 through an upper-side opening of the heat transfer gas supply passage 204 while the flow rate or the speed is regulated by the operation of the flow rate control valve 206, and is discharged through the through hole having the lift pin 208 built in through an exhaust pipe line connected and communicating with the flexible wiring 211. The flow rate or the speed of discharge of the heat transfer gas 205 is regulated by an operation of an exhaust control valve 212 arranged on the exhaust piping. The pressure in the gap between the wafer W and the electrostatic absorbing layer 203 is increased by causing the exhaust control valve 212 to be in a “close (or blocked) state”, and the pressure is decreased by causing the exhaust control valve 212 to be in an “open (full open) state”, together with regulation of the supply of the heat transfer gas 205 to above the electrostatic absorbing layer 203.

In the plasma processing apparatus configured as described above, the wafer W is placed on the upper surface of the sample stage 101 by a conveyance robot of a vacuum conveyance vessel (not illustrated) connected to the vacuum vessel 20 and the lift pins 208. The wafer W placed on the upper surface of the sample stage 101 is electrostatically absorbed on the electrostatic absorbing layer 203.

The plasma processing apparatus has a configuration to supply the heat transfer gas 205 to the gap formed between the back surface of the wafer W electrostatically absorbed on the sample stage 101 and the electrostatic absorbing layer 203, balance force in an up direction (floating force) that acts on the back surface of the wafer W by the gas pressure in the gap, and the electrostatic absorbing force (absorbing force) that acts on the wafer W by the power supplied to the inner electrode 203-1 of the electrostatic absorbing layer 203, and floating and supporting the wafer W above the electrostatic absorbing layer 203 in a noncontact state. That is, in a case of electrostatically absorbing, fixing, and holding the wafer W on the sample stage 101, supplying the heat transfer gas to the back surface of the wafer, and performing plasma processing, like a conventional case, the electrostatic absorbing force is set not to allow the wafer W to float against the pressure of the heat transfer gas that exhibits the heat transfer effect. In the present embodiment, the wafer W is floated against the electrostatic absorbing force by making the gas pressure on the back surface of the wafer, and is held above the sample stage in a noncontact manner.

The heat transfer gas is supplied through the heat transfer gas supply passage 204 to the gap between the electrostatic absorbing layer 203 and the back surface of the wafer W, the gap being a center-side area inside the sealing portion 210, in a state where the wafer W is electrostatically absorbed on the sample stage 101. The supplied heat transfer gas 205 is diffused in the gap in the center-side area formed by the sealing portion 210 having a predetermined height, and flowout of the heat transfer gas to an outer periphery of the wafer W is prevented in the place of the sealing portion 210. That is, conductance in the sealing portion 210 is decreased. The decrease in the conductance facilitates filling of the heat transfer gas 205 in the gap in the center-side area. From this, regarding gas pressure distribution of the back surface of the wafer W corresponding to the inside of the ring-like sealing portion 210 into which the heat transfer gas 205 is supplied, variation in in-plane distribution is decreased and is more uniformly approximated, and heat transfer performance between the wafer W and the sample stage 101 in the gap is more uniformly approximated. This similarly occurs if the heat transfer gas pressure is made higher to float the wafer W from the sealing portion 210.

When the wafer W is held above the electrostatic absorbing layer 203 in a noncontact manner, magnitude h2 of a gap between a flat upper surface of the sealing portion 210 and the back surface of the wafer W and magnitude h1 of the gap between the surface of the electrostatic absorbing layer 203 on the center-side of the sealing portion 210 and the back surface of the wafer W satisfy h1>h2. Then, the sealing portion 210 is set to have the small gap h2 by which the sealing portion 210 is not in contact with the back surface of the wafer W, and the magnitude of the gap h1 in an inside area of the sealing portion 210, which is a total of the height of the sealing portion 210 and the gap h2, is set to a gap by which the sufficient heat transfer effect by the heat transfer gas in the inside area of the sealing portion 210 can be obtained. For example, the magnitude of the gap h1 is 15 to 150 pm. The space including the gaps h1 and h2 is in a communication state with the space in the processing chamber 33 in the outer periphery of the wafer W.

Balance between the floating force and the absorbing force acting on the wafer W is performed in such a manner that the gap h2 is caused in the outer peripheral portion of the wafer W corresponding to the sealing portion 210 as the wafer W is floated, the heat transfer gas flows out through the gap, and the heat transfer gas pressure in the gap h1 in the inside area of the sealing portion 210 is balanced in the relationship of a pressure difference from the pressure in the processing chamber 33, and of the absorbing force. The gaps h1 and h2 become larger and a flowout amount of the heat transfer gas is increased as the heat transfer gas pressure becomes higher, and the gaps h1 and h2 become smaller and the flowout amount of the heat transfer gas is decreased as the heat transfer gas pressure is decreased.

By providing the ring-like sealing portion 210 against the outer peripheral portion of the wafer W in this way, flowout of the heat transfer gas from the sealing portion 210 is suppressed, and the heat transfer gas pressure in the back surface of the wafer W can be increased. Accordingly, the supply amount of the heat transfer gas can be suppressed and the wafer W can be held in a noncontact manner, a large capacity exhaust pump is not used to maintain the vacuum in the vacuum atmosphere, and an influence of the heat transfer gas on the processing atmosphere can be suppressed.

Further, control in floating and holding the wafer W in a noncontact manner is performed in such a manner that the relationship between the electrostatic absorbing force and the flow rate of the heat transfer gas is converted into data and stored in a control apparatus (illustration is omitted) in advance, and the flow rate control valve 206 and the direct current power source 207 are controlled by the control apparatus.

Further, in an area between the electrostatic absorbing layer 203 and the wafer W, where the gap is formed, when the heat transfer gas 205 is supplied toward the back surface of the wafer W through the heat transfer gas supply passage 204, and the wafer W is separated from the upper surface of the sealing portion 210 and floating of the wafer W is started, a place where the gas pressure is highest is the opening and its vicinity of the heat transfer gas supply passage 204 in the surface of the electrostatic absorbing layer 203. From this, the back surface of the wafer W immediately above the opening of the heat transfer gas supply passage 204 serves a place that locally supports the wafer W.

In the present embodiment, such support places are provided in three or more places, corresponding to the plane of the wafer W, and are arranged such that the center of the wafer W or the center of the placing surface of the wafer W, of the electrostatic absorbing layer 203, is positioned in an area of the upper surface of the electrostatic absorbing layer 203, the area being surrounded by straight lines that connect the openings of at least the three places. Desirably, a central position of the support places is concentrically arranged with the center of the placing surface of the wafer W, of the electrostatic absorbing layer 203, and is substantially concentric with the central position of the wafer W, whereby the wafer W is pushed above the electrostatic absorbing layer 203 in a state of being in parallel to the surface of the electrostatic absorbing layer 203 from a state of being in contact with the sealing portion 210.

A holding state of the wafer W after the heat transfer gas 205 is supplied to the gap is determined in such a manner that a voltage value of the direct current power source 207 and the value of the flow rate or the speed of the heat transfer gas 205 are detected, and the control apparatus (illustration is omitted) makes a comparison with predetermined references, using the values. For example, in a case where the voltage value of the direct current power source 207 supplied to the inner electrode 203-1 is maintained constant and the gap is decreased for some reason, the floating force is increased and balanced against the increase in the electrostatic absorbing force that acts on the wafer W, and the pressure of the heat transfer gas in the back surface of the wafer W is increased. In other words, the opening area by the gap is decreased, and flowout of the heat transfer gas to the back surface of the wafer W is suppressed and the heat transfer gas pressure is increased to take a balance. That is, the flowout of the heat transfer gas is decreased, in other words, the flow rate or the speed of the heat transfer gas 205 to be supplied is decreased due to the decrease in the gap sandwiched between the upper surface of the sealing portion 210 and the back surface of the wafer W.

Flowmeters are provided in the flow rate control valves 206 respectively arranged on the plurality of heat transfer gas supply passages 204, and variation in the distances (gaps) between the wafer W and the openings above the openings of the corresponding heat transfer gas supply passages 204 can be detected from results of comparison of the magnitude of the flow rate or the speed of the heat transfer gas 205 detected by the flowmeters.

The control device sends command signals for regulating the flow rate or the speed of the heat transfer gas 205 to be supplied from the heat transfer gas supply passages 204, to operate the flow rate control valves 206, using the detected results. From this, the control device performs regulation by increasing/decreasing the magnitude of the gaps above the openings of the heat transfer gas supply passages 204 to decrease the deviation of the height of the wafer W to become parallel to the electrostatic absorbing layer 203 or to approximate the height of the wafer W to a uniform height in an in-plane direction.

Further, the control device performs an operation to regulate the voltage value of the direct current power source 207 such that the flow rate or the speed of the heat transfer gas 205 becomes the same value as an initial value of the wafer processing or a permissible value of an approximated value that can be regarded as the initial value, even when variation is caused in the electrostatic force due to change of the surface of the electrostatic absorbing layer 203 over time associated with the wafer processing. Accordingly, the variation of upward force for the wafer W, the force being formed due to the pressure of the heat transfer gas 205 supplied to the gap is decreased, and change of the height of the gap over time is suppressed.

Further, to suppress shift of the position of the wafer W in the radial direction of the sample stage 101 (side shift) while supporting the wafer W in a noncontact manner, the outer diameter of the inner electrode 203-1 is set to the same value as the outer diameter of the wafer W or an approximated value that can be regarded as the same value. Accordingly, a separation distance between the wafer W and the outer peripheral portion of the inner electrode 203-1, which have substantially the same diameter, becomes shortest, and the electrostatic absorbing force becomes strong. Further, the electrostatic absorbing force having an inclination in the same direction as the wafer W acts between the inner electrode 203-1 and the wafer W when the wafer W is shifted in one direction, and force to return the shift of the wafer W, the force having a component parallel to the wafer W, is caused in the electrostatic absorbing force. This force works as an alignment action, and movement of the wafer W in the radial direction (lateral direction), that is, sideslip is suppressed.

Since it is desirable to make a movement amount in the radial direction of the wafer W as small as possible, the difference between the outer diameter of the inner electrode 3-1 and the outer diameter of the wafer W is set to within ±1 mm. Further, the electrostatic force that absorbs the wafer W can be made larger as the voltage of the direct current power source 207 is made higher, and force to suppress the movement of the wafer W can be made larger.

In the present embodiment, to suppress the side shift of the wafer W at the time of supply of the heat transfer gas 205 and to hold the wafer W in a noncontact manner, first, an output value of the direct current power source 7 by which restraining force of the wafer W in a desired radial direction can be obtained is set or selected, and an output of the value is supplied to the inner electrode 203-1. After that, the pressure and the supply amount of the heat transfer gas 205 are set or selected so that the wafer W can have a desired floating amount, and the flow rate or the speed of the supply of the heat transfer gas 205 is regulated so that the set value can be obtained.

Usually, the side shift of the wafer W is suppressed as described above. However, if movement (sideslip) of the wafer W accidentally occurs for some reason, the electrostatic force that acts to absorb and support the wafer W becomes too small, and thus the wafer W cannot be held and may be dropped from the position above the sample stage 101.

In the present embodiment, a ring-like shift prevention member 209 arranged outside the wafer W and having a predetermined gap between the shift prevention member 209 and an outer peripheral edge of the wafer W is provided on the upper surface of the electrostatic absorbing layer 203. The gap is set to a gap by which the wafer W and the shift prevention member 209 are not in contact in a range where the alignment action on the wafer W by the electrostatic absorbing force is caused. Further, the shift prevention member 209 has a height with which at least a side surface of the wafer W comes in contact when the wafer W is floated. Note that the shift prevention member 209 is configured from an insulating body member made of a material having resistance to plasma, and is configured from a ceramic material in this case, similarly to the insulating body 203-2. The shift prevention member 209 can prevent the movement of the wafer W by a predetermined distance or more in the radial direction of the wafer W, and can suppress the position shift amount of the wafer W to exceed a permissible value.

In a case of removing the wafer W from the sample stage 101 and carrying out the wafer W outside the processing chamber 33, a process of removing electricity is conducted, in which inverted polarities from the state of holding the wafer W are provided to the inside inner electrode 203-1a and the outside inner electrode 203-1b to offset the polarized and formed charges, without forming the plasma 43 in the processing chamber 33. After that, the lift pins 208 are moved upward by an operation of a drive actuator (not illustrated) to lift and separate the wafer W from the sample stage 101, and the wafer W is carried out outside the processing chamber 33 with the conveyance robot (not illustrated).

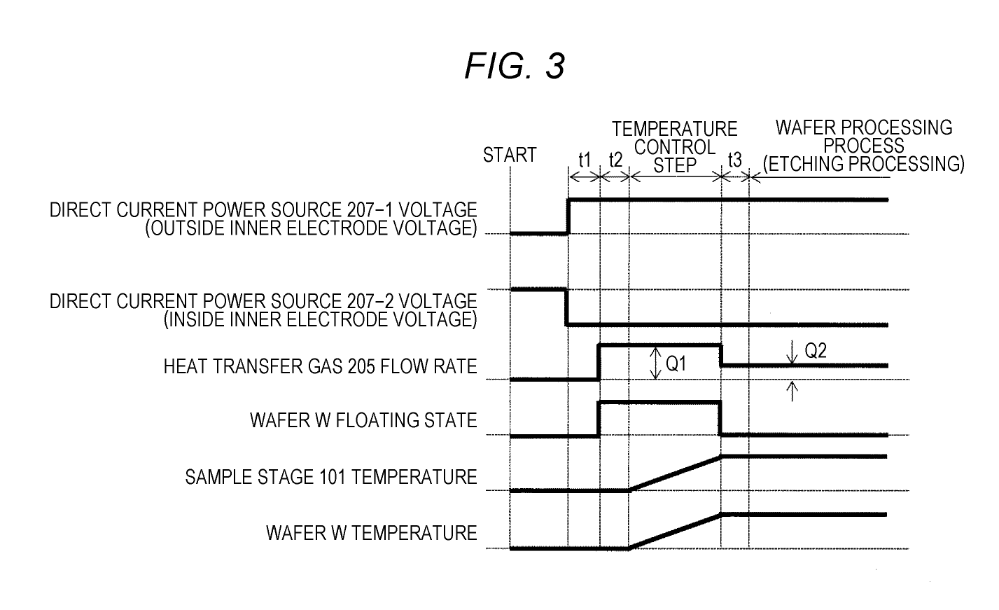

An operation of the above-described plasma processing apparatus will be described using FIG. 3. FIG. 3 is a time chart illustrating a flow of an operation of processing performed by the plasma processing apparatus according to the embodiment illustrated in FIG. 1. FIG. 3 illustrates typical processing applied to the wafer W in the plasma processing apparatus 100.

FIG. 3 illustrates relationship among the voltage of the direct current power source 207 for electrostatic absorption applied to the inner electrode 203-1 from a state where the wafer W is placed on the sample stage 101, the flow rate of the heat transfer gas supplied to the back surface of the wafer W, the floating state of the wafer W on the sample stage 101, the temperature of the sample stage 101, and the temperature of the wafer W.

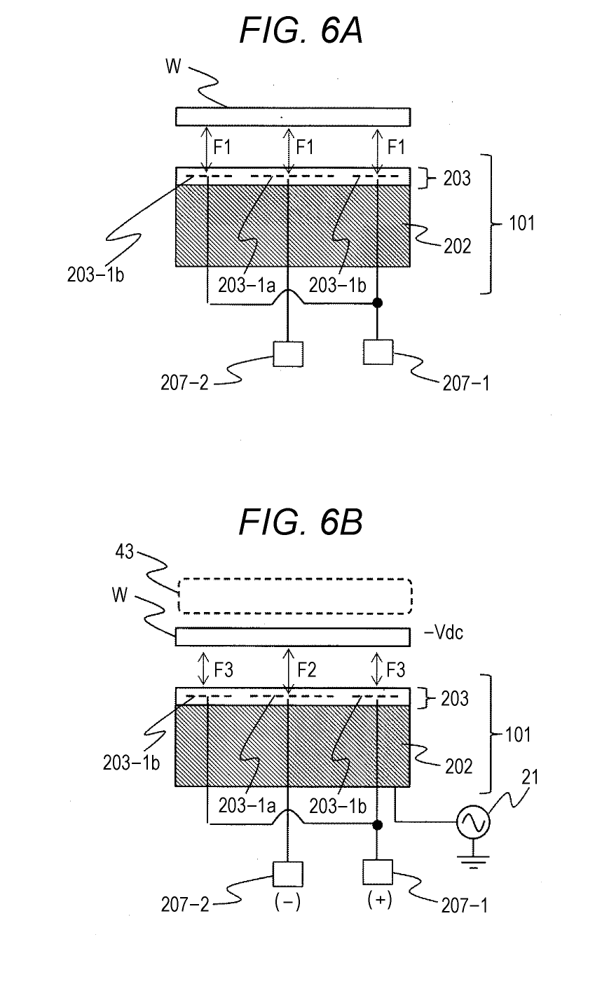

As described above, the inner electrode 203-1 of the electrostatic absorbing layer 203 is a bipolar electrode, and a direct current power source 207-2 is electrically connected to the inside inner electrode 203-1a and a direct current power source 207-1 is electrically connected to the outside inner electrode 203-1b, and supply power to the respective electrodes (see FIG. 6A describe below). First, the power is supplied from the direct current power sources 207-2 and 207-1 to the inside inner electrode 203-1a and the outside inner electrode 203-1b on the basis of the command signals from the control device, and electrostatically absorbs the wafer W on the electrostatic absorbing layer 203 to absorb and hold the wafer W on the sample stage 101. In this case, a positive potential is provided to the outside inner electrode 203-1b, and a negative potential is provided to the inside inner electrode 203-1a. In a case where the supply of the heat transfer gas 205 to the back surface of the wafer W is earlier than the application of the voltages of the direct current power sources 207-1 and 207-2, there is no restraint by the electrostatic absorbing force, and thus the wafer W may be floated or side-slipped by the pressure of the heat transfer gas.

Therefore, a predetermined time difference t1 is taken from the supply of the power by the direct current power source 207, and the flow rate control valve 206 is regulated on the basis of the command signal from the control device, in this case, the heat transfer gas 205 is supplied at a flow rate Q1. When the inside area of the sealing portion 210, of the back surface of the wafer W, is filled with the supplied heat transfer gas 205 and the gas pressure in the space becomes high, and the upward floating force acting on the wafer W becomes larger than the electrostatic absorbing force of the wafer W, the wafer W is floated from the upper surface of the sealing portion 210 and rises, and is held in a noncontact state with respect to the electrostatic absorbing layer 203 at a position of the height where the electrostatic absorbing force and the floating force are balanced.

Next, a temperature control step of the sample stage 101 is started after the elapse of a time difference t2 determined in advance as a time until the position of the floated wafer W is stabilized at the predetermined height. Alternatively, the temperature control step of the sample stage 101 is started after the floating height of the wafer W falling within a predetermined permissible range is detected by the control device, using the outputs of the flowmeters of the flow rate control valves 206 and the voltage value of the direct current power source 207. The temperature control changes the temperature of the sample stage 101 on the basis of the command signal from the control device, in this case, raises a refrigerant temperature of the temperature control unit 26 to change the temperature of the sample stage to be high. Accordingly, the heat is conducted between the sample stage 101 and the wafer W through the heat transfer gas in the back surface of the wafer W, and the temperature of the wafer W is changed in accordance with the temperature of the sample stage 101, whereby regulation of the temperature of the wafer W is performed. Note that the temperature of the sample stage 101 before the temperature control is set to the temperature of the wafer W carried into the processing chamber 33, in this case, an ordinary temperature.

Alternatively, the temperature adjustment of the sample stage 101, that is, increase/decrease in the temperature may be performed in such a manner that a heating element such as a heater is arranged inside the electrode block 202 or in the electrostatic absorbing layer 203, and the power to be supplied to the heating element is regulated to increase/decrease a calorific value of the heating element.

The temperature control step of the wafer W is performed in a noncontact state where the wafer W is floated. Therefore, occurrence of rubbing, which occurs due to a difference in thermal expansion between the members in regulation of the temperature of the wafer W, which is performed in a contact state, is suppressed in principle, and arising of fine particles and fragments that become a cause of foreign substances by sliding is decreased and a yield of the processing of the wafer W is improved.

When the temperature of the wafer W reaching the temperature suitable for processing conditions of the wafer and being stabilized is detected, the flow rate control valves 206 are controlled on the basis of the command signals sent from the control device, and the supply amount of the heat transfer gas 205 is decreased from the flow rate Q1 to Q2. Accordingly, the electrostatic absorbing force>the floating force is made, and the wafer W is lowered, and is placed on and comes in contact with the placing surface of the electrostatic absorbing layer 203 from the noncontact state.

When the back surface of the wafer W being in contact with the upper surface of the sealing portion 210 and being supported by the sample stage is detected by the control device from the flow rate or the speed of the heat transfer gas 205, a processing step of the wafer W, in this case, etching processing is started after the elapse of a time difference t3.

In a case of performing the etching processing using three or more processing steps for each film layer of an object to be processed having a film structure, a step of regulating the temperature of the wafer W to a temperature in a range suitable for the next processing step is provided between each two processing steps, and the temperature control of the wafer W is performed in a noncontact manner, as described above. When the temperature of the wafer becomes a predetermined value, the wafer is absorbed and held on the sample stage 101, the processing of the wafer is performed, and the temperature control step and the wafer processing step are repeatedly performed as needed.

Further, in the processing operation illustrated in FIG. 3, the temperature of the wafer W is increased after the time difference t2 after the wafer W is floated. However, in a case where there is a temperature difference between the initial temperature of the sample stage 101 and the temperature of the wafer W, the temperature of the wafer W is changed from when the wafer W is electrostatically absorbed. However, the heat transfer action by the gas does not work before the heat transfer gas is supplied, and thus the temperature change of the wafer W in the time difference t1 is small, and the wafer W becomes in a noncontact state after the heat transfer gas is supplied. Therefore, rubbing between the wafer W and the sample stage 101 can be substantially ignored.

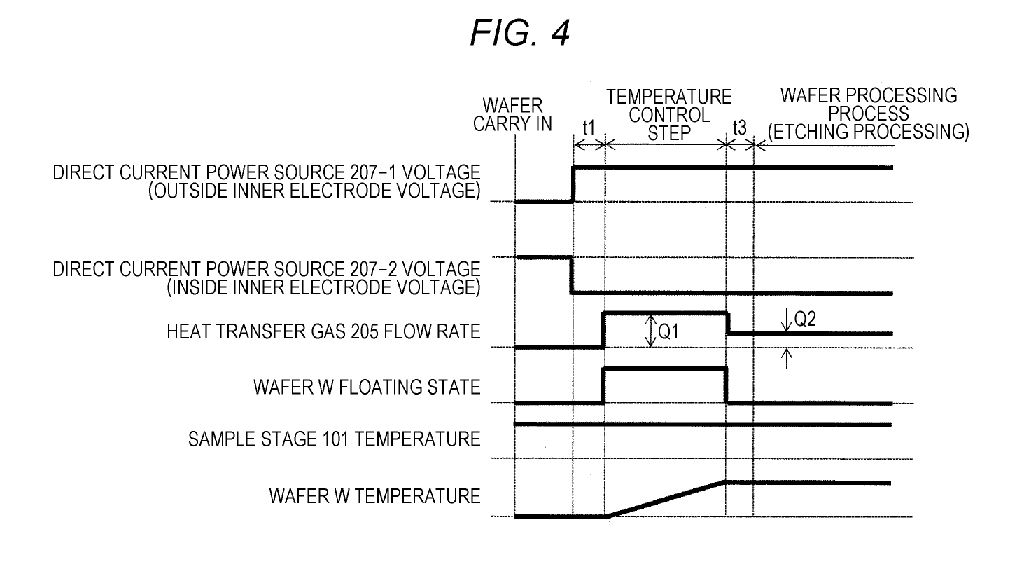

Next, FIG. 4 illustrates another example of the temperature control step in FIG. 3. FIG. 4 is a time chart illustrating a flow of an operation of processing performed by the plasma processing apparatus, similar to FIG. 3.

In FIG. 4, operations of the voltages of the direct current power sources 207-1 and 207-2, the flow rate of the heat transfer gas 205, and the floating state of the wafer W are similar to those of FIG. 3, and description is omitted. A different point of FIG. 4 from FIG. 3 is that the temperature of the sample stage 101 is set to the temperature of at the time of the wafer processing and controlled to the fixed temperature, and the temperature of the wafer W is adjusted with the control of the sample stage 101.

The temperature of the wafer W is set to a temperature (usually, a room temperature) in a vacuum conveyance chamber when the wafer W is carried into the processing chamber 33. The temperature of the sample stage 101 is set to a higher or lower temperature than the room temperature, in this case, a higher processing temperature. After the wafer W is placed on the electrostatic absorbing layer 203 and is electrostatically absorbed, the heat transfer gas 205 at the flow rate Q1 is supplied between the wafer W and the electrostatic absorbing layer 203. Accordingly, after the time difference t1, the wafer W is floated above the electrostatic absorbing layer 203 and is supported in a noncontact manner, and heat is transferred through the heat transfer gas between the sample stage 101 and the wafer W, and the temperature of the wafer W is regulated to the temperature suitable for the processing performed next. In the temperature control step, when the temperature difference between the wafer W and the sample stage 101 falling within a predetermined permissible range is detected, the supply amount of the heat transfer gas 205 is decreased to the flow rate Q2, and the wafer W is lowered to come in contact with the electrostatic absorbing layer 203. After that, similarly to FIG. 3, the processing step of the wafer is performed after the time difference t3.

Note that, in the case where the temperature of the sample stage 101 is made constant like the present example, detecting the temperature difference between the sample stage 101, the electrode block 202, or the electrostatic absorbing layer 203, and the wafer W is difficult by means such as a sensor. Therefore, a time in which the temperature difference falls within the desired permissible range and the temperature is stabilized is obtained in advance by an experiment or a test before the processing of the wafer W by the plasma processing apparatus 100 is performed, and the temperature control step of regulating the temperature while floating the wafer W is performed by the time.

The temperature control of FIG. 3 is advantageous when the difference between the processing temperature of the wafer W and the temperature of the wafer W to be controlled is small, or when the temperature control of the sample stage 101 can be performed in a short time. The temperature control of FIG. 4 is advantageous when the difference between the processing temperature of the wafer W and the temperature of the wafer W to be controlled is large, or when the temperature control of the sample stage 101 requires time.

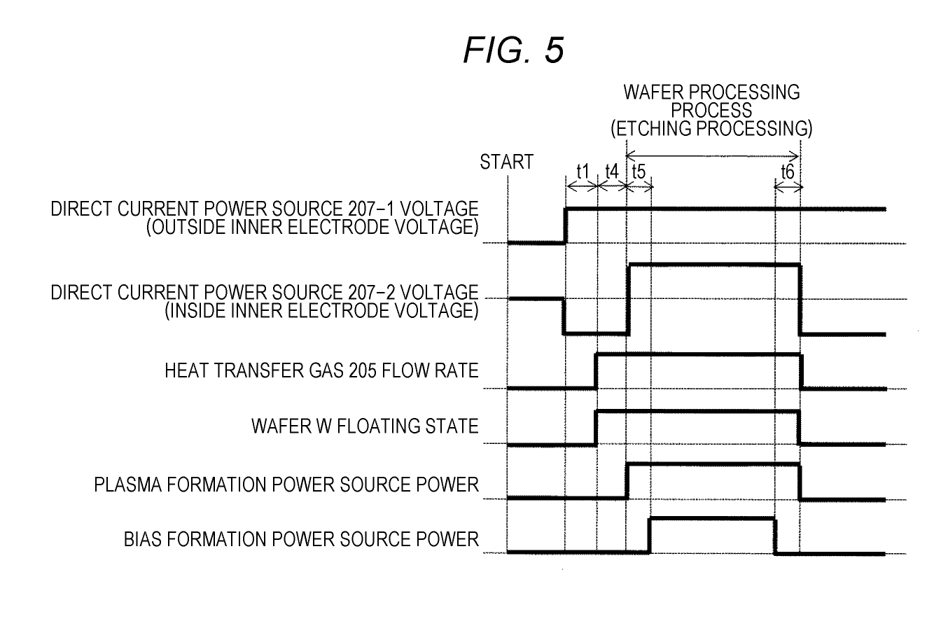

Next, as another example of the processing by the plasma processing apparatus, an example of performing etching processing in a state where the wafer W is held in a noncontact manner will be described using FIG. 5. FIG. 5 is a time chart illustrating another example of a flow of an operation of the processing performed by the plasma processing apparatus.

A substantially different point of the present example from FIGS. 3 and 4 of the former examples is that, in the etching processing of the wafer W, the etching processing is performed for the wafer W held in a noncontact manner in the present example, while the wafer W held in a noncontact manner is brought in contact with and held and the etching processing is performed for the wafer

W.

FIG. 5 illustrates relationship among the voltage of the direct current power source 207 for electrostatic absorption applied to the inner electrode 203-1 from the state where the wafer W is placed on the sample stage 101, the flow rate of the heat transfer gas supplied to the back surface of the wafer W, the floating state of the wafer W on the sample stage 101, power of the power source for plasma formation, and power of the power source for bias formation.

Similarly to FIGS. 3 and 4 described above, the inner electrode 203-1 is a bipolar electrode, and the direct current power source 207-2 is electrically connected to the inside inner electrode 203-1a, and the direct current power source 207-1 is electrically connected to the outside inner electrode 203-1b, and supply the power to the respective electrodes (see FIG. 6B described below).

First, the power is supplied from the direct current power sources 207-2 and 207-1 to the inside inner electrode 203-1a and the outside inner electrode 203-1b on the basis of the command signals from the control device, and the wafer W is electrostatically absorbed by the electrostatic absorbing layer 203 and absorbed and held on the sample stage 101. In this case, a positive potential is provided to the outside inner electrode 203-1b and a negative potential is provided to the inside inner electrode 203-1a.

The predetermined time different t1 is taken from the supply of the power by the direct current power source 207, the flow rate control valves 206 are regulated on the basis of the command signals from the control device, and the heat transfer gas 205 is supplied to the gap between the wafer W and the electrostatic absorbing layer 203. When the inside area of the sealing portion 210, of the back surface of the wafer W, is filled with the supplied heat transfer gas 205 and the gas pressure in the space becomes high, and the upward floating force acting on the wafer W becomes larger than the electrostatic absorbing force of the wafer W, the wafer W is floated and rises from the upper surface of the sealing portion 210, and is held in a noncontact state with respect to the electrostatic absorbing layer 203 at the position of the height where the electrostatic absorbing force and the floating force are balanced.

Next, although illustration of the time chart is omitted, the processing gas 35 is supplied to the processing chamber 33 through the gas introduction pipe 34 connected to the vacuum vessel 20. At this time, the processing gas 35 in the interior of the processing chamber 33 is exhausted through the exhaust port 36 by the turbo molecular pump 38, the flow rate or the speed of the exhaust is regulated with the pressure regulation valve 37, and the pressure in the processing chamber 33 is regulated to a value suitable for the processing of the wafer W by balance between the supply and the exhaust of the processing gas 35.

In this state, after the elapse of a time difference t4 from when the supply of the heat transfer gas 205 is started, the power for forming the plasma 43 is supplied to the processing chamber 33. That is, the microwave 40 oscillated by the microwave oscillator 39 is supplied to the processing chamber 33 and the magnetic field by the solenoid coils 42 is formed in the processing chamber 33. Accordingly, the processing gas 35 supplied in the processing chamber 33 is excited, the plasma 43 is formed in the processing chamber 33, and the wafer processing step is started.

Note that, in the present example, the supply of the processing gas is performed after the wafer W is held in a noncontact manner. However, from a perspective of shortening of throughput, the electrostatic absorbing process of the wafer W and the noncontact holding process of the wafer W by the supply of the heat transfer gas 205 may be sequentially performed, while the supply of the heat transfer gas 205 is started and the pressure adjustment in the processing chamber 33 is performed after the wafer W is placed on the sample stage 101 and a carrying-in entrance of the wafer in the vacuum vessel 20 is closed. In either case, the processing pressure adjustment in the processing chamber 33 and the height position of the floated wafer W are stabilized during the time difference t4. That is, the floating force acting on the wafer W is influenced by the pressure in the processing chamber 33. Therefore, when the pressure in the processing chamber 33 is stabilized, the noncontact holding state of the wafer W is stabilized.

Next, the power for plasma formation is supplied and after the elapse of a time difference t5, bias power for providing a bias potential to the wafer W is supplied from the high-frequency power source 21 to the sample stage 101, and substantive etching processing of the wafer W is started. Note that the time difference t5 is a time until the power for plasma formation is supplied and the intensity of the plasma 43, the state of the potential, and the like are stabilized, and is a time until the plasma 43 is stabilized from the supply of the power for plasma formation, which is detected by the control device (not illustrated) or obtained by an experiment or the like in advance. Further, the wafer W is floated from the sample stage 101 and has the gap h1. However, the gap h1 is a very small gap, as described above, and does not influence on formation of a high-frequency circuit of high-frequency bias formed through the plasma, and a self-bias potential is formed in the wafer W, similarly to the case where the wafer W is placed on the sample stage 101. Accordingly, charged particles such as ions in the plasma 43 are attracted by and collide with the upper surface of the wafer W, and a film layer to be processed of the wafer W is anisotropy-etched, and the etching processing is facilitated.

Further, in the present example, immediately after the supply of the power for plasma formation is started or the plasma 43 is formed in the processing chamber 33, the voltages supplied from the direct current power sources 207-1 and 207-2 are regulated to have the same potential and the same polarity. In this case, the voltage of the inside inner electrode 203-1a is regulated from the negative value to the same positive value as the outside inner electrode 203-1b. Accordingly, monopole electrostatic absorption is realized, and when the self-bias potential is formed in the wafer W, the same electrostatic absorbing force acts on the plane of the wafer W, corresponding to the inside and outside inner electrodes 203-1a and 203-1b, and stable noncontact holding becomes possible.

When termination of the etching of the film layer to be processed of the wafer W or the elapse of the time for performing the processing determined in advance is detected by the control device, the supply of the power for bias formation from the high-frequency power source 21 is stopped on the basis of the command signal from the control device. After the elapse of a predetermined time difference t6, the supply of the power for plasma formation is stopped, and the wafer processing step is terminated. With this, the voltage supplied from the direct current power source 207-2 to the inside inner electrode 203-1a is regulated to the same negative potential as that before the wafer processing step. Note that switching of the positive potential to the negative voltage by the direct current power source 207-2 is performed at the same time with or immediately before the stop of the supply of the power for plasma formation. Further, the flow rate or the speed of the heat transfer gas 205 is decreased and the floating force of the wafer W is decreased, and the wafer W is lowered and comes in contact with the sealing portion 210 of the electrostatic absorbing layer 203, and is held on the sample stage 101. Note that the decrease in the supply of the heat transfer gas 205 may be performed within the time difference t6.

According to the present example, the wafer W can be held above the electrostatic absorbing layer 203 in a noncontact manner even during the processing using the plasma 43 of the wafer W, and especially, in a case where a heat input from the plasma 43 to the wafer W is large during the processing of the wafer W, and thus the wafer W and the sample stage 101 are heated and noticeable thermal expansion is caused, rubbing between the back surface of the wafer W and the surface of the sample stage 101 is not caused and arising of contamination or foreign substances is decreased, and the yield can be improved.

FIGS. 6A and 6B are vertical sectional views schematically illustrating the electrostatic absorbing force formed in the sample stage illustrated in FIG. 2A. FIG. 6A corresponds to FIGS. 3 and 4 described above, and illustrates the electrostatic absorbing force in a state where the plasma 43 is not generated above the sample stage 101 in the processing chamber 33.

The areas of the outside inner electrode 203-1b and the inside inner electrode 203-1a of the electrostatic absorbing layer 203 are equal, and the voltages having different polarities and having an equal absolute value are formed in the respective electrodes by the power from the direct current power source 207-1 and the direct current power source 207-2 electrically connected with the respective electrodes. For example, in a case where the voltages of +1000 V and −1000 V are applied to the respective electrodes, absorbing force F1 toward the electrostatic absorbing layer 203 works between the electrodes and the wafer W. Therefore, uniform downward electrostatic absorbing force acts on the wafer W as a whole.

FIG. 6B corresponds to FIG. 5 described above, and illustrates the electrostatic absorbing force in a state where the plasma 43 is generated in the processing chamber 33. FIG. 6B illustrates a case in which the plasma 43 is formed in the processing chamber 33 and the high-frequency power is supplied from the high-frequency power source 21 for bias formation to the electrode block 202 that configures the sample stage 101, and the voltages having different polarities are applied to the inside inner electrode 203-1a and the outside inner electrode 203-1b, similarly to FIG. 6A.

In this condition, a minus potential −Vdc is generated in the wafer W as the self-bias potential. The electrostatic absorbing force is proportional to the difference in the potential between the inner electrode 203-1 and the wafer W, and thus when the potential of the wafer W is changed, the potential difference between the wafer W and the inner electrode 203-1 in the electrostatic absorbing layer 203 becomes small on the plus side and becomes large on the minus side. Absolute values of the potential differences are different between an inside and an outside of the wafer W, variation of the electrostatic absorbing force acting on the wafer W becomes large in an in-plane direction of the wafer W. That is, in a case where +1000 V is applied to the outside inner electrode 203-1b as the positive voltage, and −1000 V is applied to the inside inner electrode 203-1a as the negative voltage, and −300 V is generated in the wafer W as the self-bias potential, the potential difference between the inside inner electrode 203-1a and the wafer W becomes 1300 V, and the potential difference between the outside inner electrode 203-1b and the wafer W becomes 700 V. Therefore, regarding electrostatic absorbing force F2 (inside) and F3 (outside) acting on the wafer W above the respective inside inner electrode 203-1a and outside inner electrode 203-1b, the electrostatic absorbing force F2 becomes larger (F2 >F3), and variation in the absorbing force is caused in the plane of the wafer W.

Meanwhile, since the pressure of the heat transfer gas in the back surface of the wafer W is uniform, balance between the floating force of the wafer W and the electrostatic absorbing force becomes nonuniform in the plane of the wafer W, the floating height of the wafer W differs between the inside and the outside of the wafer W, and in this case, inside absorbing force becomes large, and the central portion of the wafer W may come in contact with the electrostatic absorbing layer 203. Therefore, in the example of FIG. 5, the polarity of the voltage to be applied to the inside inner electrode 203-1a is switched to have the monopole electrostatic absorption, and the potential is made the same as the potential to be applied to the outside inner electrode 203-1b, during the processing of the wafer W using the plasma 43, so that no difference is caused in the absorbing force. Note that, in this example, the monopole electrostatic absorption is employed. However, the dipole electrostatic absorption may be used, the positive potential to be applied to the outside inner electrode 203-1b may be made large by the self-bias, and the negative potential to be applied to the inside inner electrode 203-1a may be made small by the self-bias, so that no difference is caused in the absorbing force.

Note that the examples of FIGS. 3, 4, and 5 described above illustrate examples of the operation of the processing of the processing apparatus that floats the wafer W in the vacuum vessel and holds the wafer W in a noncontact manner, and these examples may be selected or combined as needed and performed.

### [Modification]

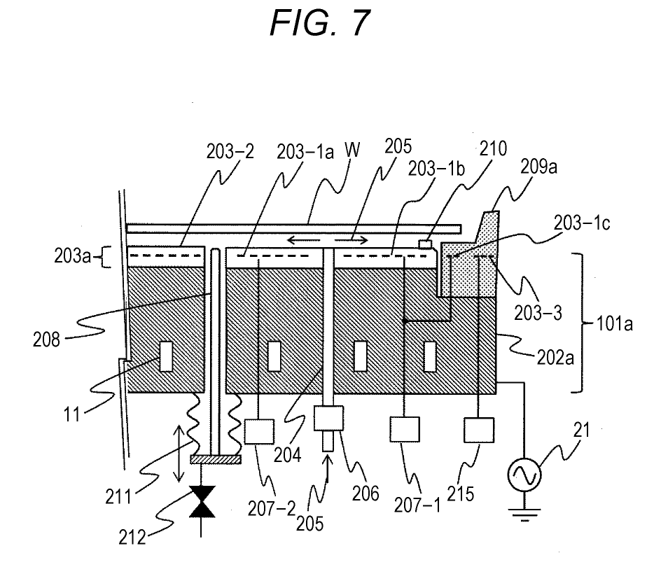

Next, a modification of the sample stage 101 illustrated in FIGS. 2A and 2B will be described using FIG. 7. FIG. 7 is a vertical sectional view illustrating an outline of a configuration of a sample stage of a plasma processing apparatus illustrated in FIG. 1.

Different points of FIG. 7 from FIG. 2A are that an outer diameter of a high-center portion serving as a wafer placing surface of an electrode block 202 is made slightly smaller than an outer diameter of a wafer W, while the outer diameter of the high-center portion in FIG. 2B is larger than the outer diameter of the wafer W, and a ring cover having an inner electrode is provided on a step portion in an outer periphery of the electrode block 202. In FIG. 7, the same reference sign as that of FIG. 2A and 2B represents the same member, and description is omitted.

As illustrated in FIG. 3, an electrostatic absorbing layer 203a is provided on an upper surface of an electrode block 202a of a sample stage 101a, and a sealing portion 210 similar to the above description is provided in an outer peripheral portion of an upper surface of the electrostatic absorbing layer 203a. Further, a ring cover 209a made of an insulating body is arranged on the step portion in an upper outer peripheral edge of the electrode block 202a. A ring-like electrode 203-1c having nearly the same outer diameter as the outer diameter of the wafer W, and buried in the same height as the height of an inside inner electrode 203-1a and an outside inner electrode 203-1b is provided in an interior of the ring cover 209a. The electrode 203-1c is connected with a direct current power source 207-1 connected to the outside inner electrode 203-1b. Further, an electrode 203-3 is buried in the interior of the ring cover 209a and outside the electrode 203-1c with a distance. A direct current power source 215 is connected to the electrode 203-3. A ring-like protruding portion having an inner diameter slightly larger than the outer diameter of the wafer W, and having a mortar-like inclination is formed on an upper outer periphery of the ring cover 209a.

In the sample stage 101a having the above-described configuration, an outer peripheral edge portion of the wafer W further protrudes to an outer periphery-side in the entire periphery than an outer peripheral edge of the protruding portion in an upper center-side area of the electrode block 202a is, in a state where the wafer W is placed on the electrostatic absorbing layer 203a. The ring cover 209a is configured from a material made of a dielectric having resistance to plasma, such as an alumina ceramic or quarts, and covers an upper surface of the step portion of the electrode block 202a and a protruding portion-side wall surface of a cylindrical shape that forms the step portion. Even when the ring cover 209a is scraped by collision with charged particles in entering plasma 43, or the amount of deposit by plasma processing is increased, only the ring cover 209a can be detached from the electrode block 202a and replaced. Further, the electrode 203-1c is provided in the ring cover 209a, and a function to position the wafer W in a radial direction on the electrostatic absorbing layer 203 is added. The ring-like protruding portion in the upper portion of the ring cover 209a surrounds the outer peripheral edge of the wafer W and extends more upward than an upper surface of the wafer W in a state where the wafer W is placed on the electrostatic absorbing layer 203, and prevents unexpected shift of the wafer W and can prevent problems such as drop of the wafer W because the position shift with respect to the sample stage 101 becomes large, and unavailability of conveyance of the wafer W.

Further, the power is supplied from the direct current power source 215 to and a negative voltage is formed in the electrode 203-3 positioned outside the outer diameter of the wafer W as viewed from above during the processing of the wafer W. Accordingly, a negative potential by the electrode 203-3 is formed in an outer peripheral portion of the wafer W, against the wafer W in which a minus potential −Vdc is generated as a self-bias potential, and the position shift of the wafer W can be suppressed by Coulomb force (repulsive force).

Note that it is obvious that, in a plasma processing apparatus having the configuration of the present example, the operation of the flow illustrated in the first embodiment can be performed and the wafer W can be processed.

### Second Embodiment

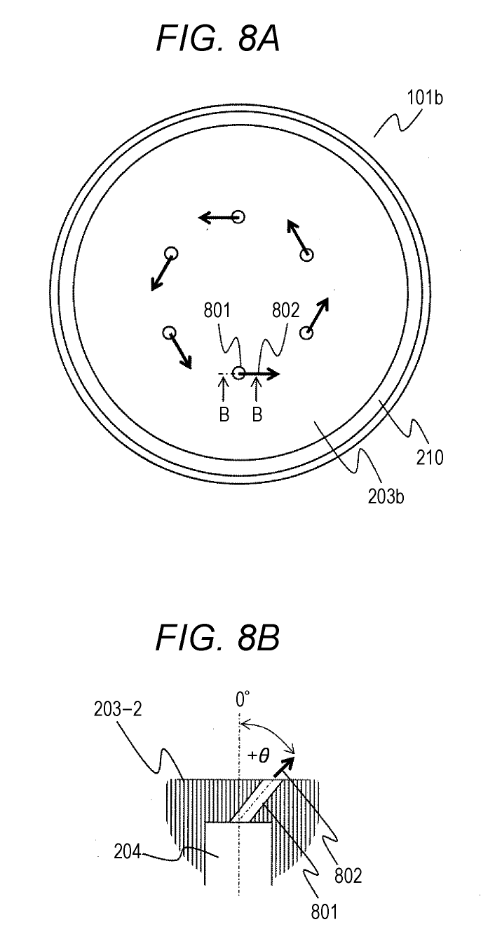

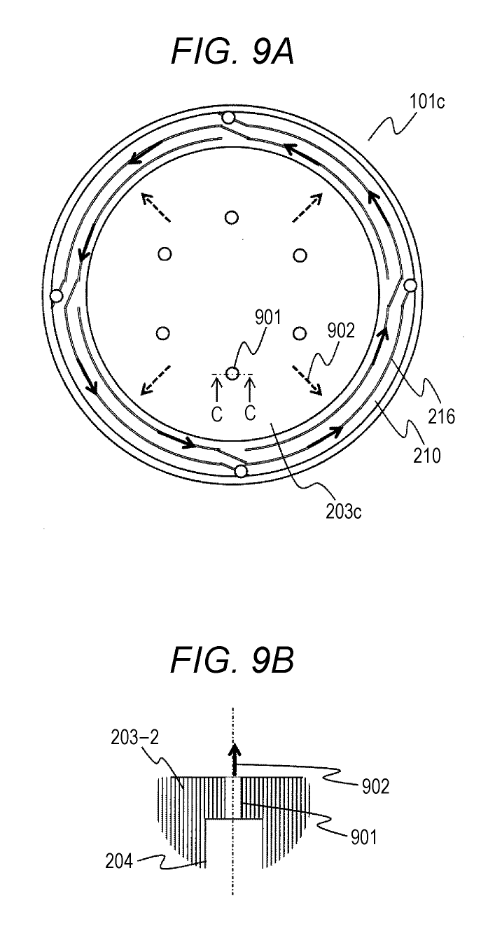

Hereinafter, a second embodiment of the present invention will be described using FIGS. 8A and 8B and 9A and 9B. The second embodiment is an example of rotating a wafer W floated and held in a noncontact manner in a decompressed atmosphere. FIGS. 8A and 8B are diagrams illustrating an outline of a configuration of a sample stage of a plasma processing apparatus according to the embodiment of the present invention. FIG. 8A is a plan view of the sample stage as viewed from an upper surface, and FIG. 8B is a vertical sectional view schematically illustrating a configuration of a heat transfer gas supply passage when FIG. 8A is viewed from BB.

A different point of FIGS. 8A and 8B from the sample stage illustrated in FIGS. 2A and 2B is a blow-out angle of a heat transfer gas through a heat transfer gas supply hole opened in a wafer placing surface of the sample stage. While the holes are provided to allow the gas to blow out at a right angle with respect to the back surface of the wafer W in FIGS. 2A and 2B, holes are provided to allow the gas to blow out inclined at the same angle through a plurality of the heat transfer gas supply passages provided in a circumferential direction in the present example. Illustration of electrodes and the like that form electrostatic force for generating force to absorb the wafer in a direction of the sample stage is omitted. Other configurations are similar to FIGS. 2A and 2B, and description is omitted.

As illustrated in FIG. 8A, a plurality of heat transfer gas supply passages 204a is arranged on a circumference with at least one radius in a center-side area surrounded by a sealing portion 210, of a electrostatic absorbing layer 203b in a sample stage 101b, and an opening 801 inclined at an angle 0 is provided in a tip end of the heat transfer gas supply passage 204a, as illustrated in FIG. 8B, and is arranged in an upper surface of the electrostatic absorbing layer 203b. Further, the inclinations of the openings 801 having a cylindrical shape are arranged to have the angle 0 in the same direction as viewed from the center of the electrostatic absorbing layer 203b. In this configuration, a heat transfer gas 205 is supplied to a direction 802 that makes the angle θ with respect to a back surface of the wafer W in a state where the wafer W is arranged above the electrostatic absorbing layer 203.

With this configuration, when the wafer W is floated as a result of the heat transfer gas 205 being supplied through the opening 801 to a gap between the wafer W and the electrostatic absorbing layer 203, to increase pressure in an area surrounded by the sealing portion 210 in the gap, to cause upward force to act on the wafer W, similarly to the first embodiment, shearing force of a flow of the heat transfer gas 205 works on the wafer W along the direction 802 into which the heat transfer gas 205 flows, and force to rotate the wafer W around the center of the wafer W acts. Meanwhile, the gas pressure in the gap on an inner periphery side of the sealing portion 210 acts in a direction perpendicular to the back surface of the wafer W, and the electrostatic absorbing force by the voltage applied to an inner electrode 203-1 acts on the wafer W, and displacement in an in-plane direction of the wafer W is suppressed.

In this state, the wafer W is held above the electrostatic absorbing layer 203 at a predetermined height in a noncontact manner, similarly to the first embodiment, and is rotated above the electrostatic absorbing layer 203 around the center of the wafer W or a placing surface. In the present example, the inclined angle θ of the opening 801 or a flow rate or a speed of the heat transfer gas 205 is regulated, whereby the number of rotations (rotational angular velocity) per unit time of the wafer W can be regulated.

Further, the plurality of openings 801 may be arranged such that the inclined angles θ are made different. For example, in FIG. 8A, the openings 801 of six heat transfer gas supply passages 204a are arranged in the direction 802 into which the heat transfer gas 205 flows out in a counterclockwise manner as viewed from above.

Three of the six heat transfer gas supply passages 204a may have a configuration having an axial direction of the opening 801 such that the heat transfer gas 205 flows out in a clockwise direction.

Alternatively, nine heat transfer gas supply passages 204a may be arranged in the placing surface on the inner periphery side of the sealing portion 210, of the electrostatic absorbing layer 203b, around a central axis of the placing surface, and axes of three openings 801 may be arranged at an angle where the heat transfer gas 205 flows out in the counterclockwise direction as viewed from above, three openings 801 of remaining six may be arranged in the clockwise direction, and remaining three may be arranged to make an angle at which the heat transfer gas 205 flows out in the direction perpendicular to the placing surface or a direction along a central axis of an electrode block 202. The heat transfer gas 205 is introduced into the gap between the wafer W and the electrostatic absorbing layer 203 in every group of the three openings 801, whereby different operations can be performed, including an increase (start) or a decrease (stop) in the number of rotations (rotational angular velocity) of the wafer W by either the group arranged at the clockwise angle or the group arranged at the counterclockwise angle, and maintenance of a floating state of the wafer W by the group in the perpendicular direction, and these operations can combined and used during processing of the wafer W or regulation of the temperature.

Note that, in the present example, the openings 801 are provided in the electrostatic absorbing layer 203b. However, in a case where the thickness of the electrostatic absorbing layer 203b is thin, the openings 801 may be provided in the electrode block 202,

FIGS. 9A and 9B are diagrams illustrating a schematic configuration of a modification of the sample stage illustrated in FIGS. 8A and 8B. FIG. 9A is a plan view of a sample stage as viewed from an upper surface, and FIG. 9B is a vertical sectional view schematically illustrating a heat transfer gas supply passage when FIG. 9A is viewed from CC.

In the present modification, to rotate a flow of a heat transfer gas 205 supplied to a surface of an electrostatic absorbing layer 203c of a sample stage 101c, around a central axis of the sample stage 101c, a gas groove 216 arranged in an outer periphery-side area of the electrostatic absorbing layer 203c in a ring manner is provided. The gas groove 216 is configured from at least one recess portion multiple-concentrically or spirally arranged in different radius positions around the center of the placing surface as viewed from above, in a flat upper surface of the sealing portion 210a arranged in a ring manner in an outer periphery-side area of a surface that configures a placing surface of the electrostatic absorbing layer 203c. The heat transfer gas 205 supplied to the gap on the inner periphery side of the sealing portion 210a flows in a peripheral direction in a counterclockwise manner in FIG. 9A in the recess portion of the groove, whereby shearing force to induce the rotation in the peripheral direction acts on the wafer W.

The embodiment illustrated in FIGS. 2A and 2B, the heat transfer gas 205 supplied to the gap of the back surface of the wafer W through the heat transfer gas supply passage 204 in the area on the inner periphery side of the sealing portion 210 is diffused and filled in the gap, and flows out to a processing chamber 33 through the gap between the wafer W and the sealing portion 210. That is, the heat transfer gas 205 in the gap has a flow from the center side of the wafer W toward the outer periphery side, so-called a direction 902 having a component in a radial direction, in at least the outer periphery-side area of the back surface of the wafer W.

The gas groove 216 arranged in an upper surface of the sealing portion 210a in the present example converts the direction of the flow of the heat transfer gas 205 that flows in the gap between the sealing portion 210a and the wafer W from the radial direction to the peripheral direction, and can cause the force to rotate the wafer W to efficiently act on the wafer W by the shearing force of the heat transfer gas 205 flowing in the gap in the peripheral direction. Note that at least one termination portion of the gas groove of the present example communicates with a space of an outer periphery of the sealing portion 210a through an opening arranged in an upper end portion of a side wall of the sealing portion 210a in an outer peripheral edge of an upper surface of the ring-like sealing portion 210a, and the heat transfer gas 205 flowing in the gas groove 216 flows out to the processing chamber 33 through the opening.

By use of the configuration of the sample stage of the present example illustrated in FIGS. 8A and 8B and 9A and 9B, the wafer W can be rotated around the center of the wafer W or the placing surface of the electrostatic absorbing layer 203 while being held above the electrostatic absorbing layer 203 in a noncontact manner during the processing of the wafer W, using plasma 43 formed in the processing chamber 33. From this, variation in a shape of a film layer to be processed after processing as a result of etching processing in an in-plane direction, especially, in the peripheral direction of the wafer W, can be favorably suppressed, and a yield of the processing can be improved.

Further, the timing is not limited to during the processing of the wafer W, the wafer W is rotated while being held above the electrostatic absorbing layer 203 in a noncontact manner, in a process of regulating a temperature of the wafer W, which is performed before a process of the processing of the wafer W using the plasma 43 is started, or between processes of a plurality of pieces of processing, whereby the variation in the temperature in the in-plane direction, especially, in the peripheral direction of the wafer W can be favorably suppressed, and distribution in the in-plane direction of the temperature of the wafer W suitable for the process of the processing of the film layer to be processed on the wafer W performed next can be realized, and the yield of the processing can be improved. Further, the wafer W is rotated in a state of being held in a noncontact manner above the electrostatic absorbing layer 203 at a predetermined height, whereby occurrence or expansion of position shift can be effectively suppressed even if external force of some sort that changes the position of the wafer W in the in-plane direction acts. As a result, the yield of the processing of the wafer W can be improved.

Note that, in the above-described embodiment, the plasma processing apparatus that generates the plasma 43 by an ECR using an electric field and a magnetic field of microwaves has been described. However, the present invention does not have restrictions on functions and effects and can be applied to means to form another plasma, for example, a configuration to form plasma by inductive coupling or capacitive coupling.

### Third Embodiment

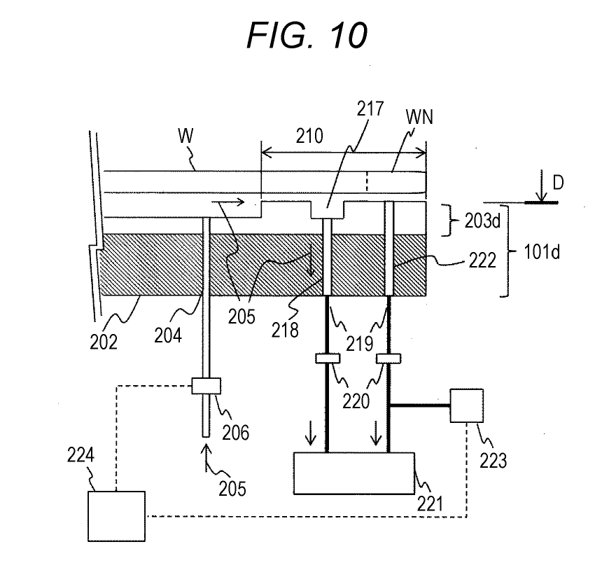

Hereinafter, a third embodiment using a sample stage of the present invention will be described using FIGS. 10 to 13A to 13C.

FIG. 10 is a vertical sectional view schematically illustrating an outline of a configuration of a sample stage of a plasma processing apparatus according to the third embodiment of the present invention. FIG. 10 illustrates enlarged principal portions of a sample stage 101d of the present embodiment.

The sample stage 101d according to the embodiment is provided in place of the sample stage 101 in the processing chamber 33 of the plasma processing apparatus illustrated in FIG. 1. Similarly to the sample stage 101 illustrated in FIGS. 2A and 2B, the sample stage 101d includes an electrode block 202 made of metal, and having an upper end portion having a cylindrical shape, and an electrostatic absorbing layer 203d made of a dielectric, which is joined with an upper surface of the electrode block 202.

A ring-like sealing portion 210b is arranged on an outer peripheral portion of the upper surface of the electrostatic absorbing layer 203d of the sample stage 101d of the present embodiment. Differences in the present example from the electrostatic absorbing layer 203 of FIGS. 2A and 2B are that exhaust paths of at least two heat transfer gasses arranged in the sealing portion 210b integrally formed with a center-side portion of the electrostatic absorbing layer 203d are provided, and a detector for detecting passage of a notch of a wafer W is arranged in one of the exhaust paths.

The exhaust paths of the heat transfer gas include an exhaust hole 218 having an opening in a bottom surface of an exhaust groove 217 arranged in a ring manner in an upper surface of the sealing portion 210b as viewed from above, and a detection hole 222 communicating with an opening arranged in the upper surface of the sealing portion 210 on an outer periphery side of the exhaust groove 217. The exhaust hole 218 and the detection hole 222 penetrating the sample stage 101d are connected with a vacuum pump 221 arranged outside a processing chamber 33 through exhaust lines 219 configured from piping in a lower surface of the sample stage 101d. With an operation of the vacuum pump 221, a heat transfer gas 205 existing in a gap between the upper surface of the sealing portion 210b and a back surface of the wafer W is discharged through the exhaust groove 217 or the opening in the upper end of the exhaust hole 218, and the opening in the upper end of the detection hole 222.

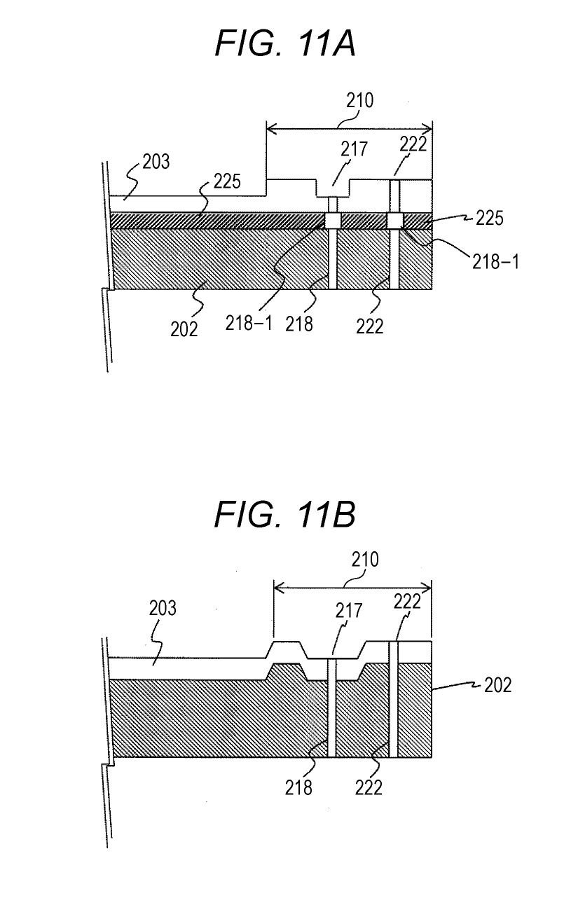

Note that the joint of the electrostatic absorbing layer 203d and the electrode block 202 provided with the exhaust groove 217, the exhaust hole 218, and the detection hole 222, and the combination thereof are not limited to the example illustrated in FIG. 10, and may have a configuration illustrated in FIGS. 11A and 11B.

FIG. 11A illustrates a configuration in which an electrostatic absorbing layer 203e is configured from a sintered member that is sintered ceramic in a disk manner, and the electrostatic absorbing layer 203e as a sintered plate and the electrode block 202 are integrally joined having a layered adhesive 225 interposed therebetween. In such a configuration, a sealing portion 210c as a ring-like protruding portion, the exhaust groove 217, the exhaust hole 218, and the like arranged on an outer periphery side of an upper surface of the electrostatic absorbing layer 203e are drilled and processed after a process of gluing the sintered plate that configures the electrostatic absorbing layer 203e to the upper surface of the electrode block 202 is performed. Note that an adhesion layer in passages of the exhaust hole 218 and the detection hole 222 is cavities 218-1, and the adhesive 225 is arranged not to block the passages of the holes.

FIG. 11B illustrates another modification in which an electrostatic absorbing layer 203f is formed by a spraying method of emitting or spraying particles of ceramics such as yttria or alumina in a semi-melted state. In this case, after an uneven shape is processed in an upper surface of an electrode block 202b, the electrostatic absorbing layer 203f is formed by the spraying, whereby the electrostatic absorbing layer 203f following the uneven shape can be formed. By such a method, a relatively large uneven shape in several hundred micron order can be formed in the surface of the sample stage 101d. In a case where necessary uneven dimensions are minute, the upper surface of the electrode block 202b is processed to be flat, and then a planar electrostatic absorbing layer 203f is formed by the spraying method, and then fine processing may just be applied to the electrostatic absorbing layer 203f.

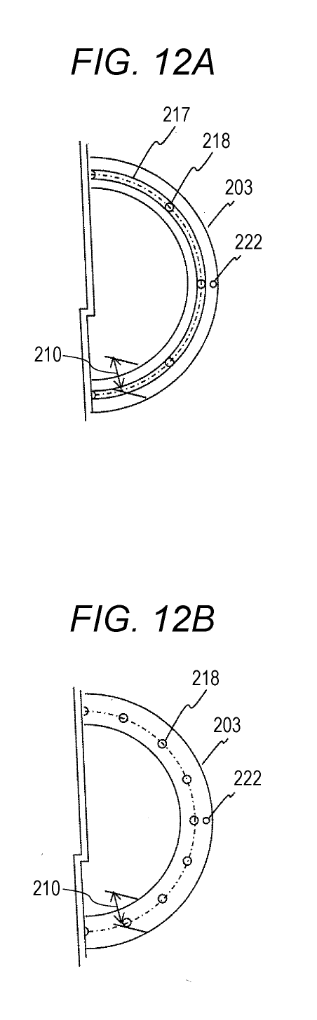

As illustrated in FIG. 12A, the exhaust groove 217, the exhaust hole 218, and the detection hole 222 configured in this way are arranged in the sealing portion 210b of the electrostatic absorbing layer 203d. The exhaust paths of the heat transfer gas include the exhaust groove 217 having a ring-like depression in an upper portion of the sealing portion 210b that surrounds a central portion of the electrostatic absorbing layer 203d having a circular shape or an equivalent shape that can be regarded as the circular shape, and a plurality of the exhaust holes 218 having an opening in a bottom surface of the exhaust groove 217 and penetrating the electrostatic absorbing layer 203 in an up and down direction. In this configuration, the heat transfer gas 205 between the sealing portion 210b and the wafer W, flowing into the exhaust groove 217, is sucked into interiors of the exhaust holes 218 that are decompressed by driving of the vacuum pump 221 through the plurality of openings, and is exhausted outside the processing chamber 33.

In the present example, a plurality of the exhaust holes 218 or the openings communicating with upper ends thereof are equally arranged or arranged in separate places that make an approximated angle that can be regarded as the equal arrangement around the center of the sample stage 101d or the electrostatic absorbing layer 203d. Variation in the amount of exhaust through every exhaust hole 218, of the heat transfer gas 205 that is exhausted through the ring-like exhaust groove 217 and the plurality of openings arranged in the bottom surface of the exhaust groove 217, is decreased, and deviation in distribution about pressure of the heat transfer gas in a peripheral direction between a back surface of an outer peripheral portion of the wafer W and the sealing portion 210b, and in a floating height of the wafer W according to the distribution can be decreased.

Further, the exhaust paths of the heat transfer gas are not limited to the above-described configuration, and a configuration in which the exhaust groove 217 of FIG. 12A is eliminated and the exhaust holes 218 are more densely arranged, as illustrated in FIG. 12B, may be employed. Further, a configuration in which the lower end portions of the exhaust holes 218 are not connected with the vacuum pump 221 through the exhaust lines 219, and are open to places communicating with the processing chamber 33, and the heat transfer gas 205 in the gap between the upper surface of the sealing portion 210e and the wafer W, the gap having higher pressure than the pressure in the processing chamber 33, is caused to flowout to the processing chamber 33 through the exhaust holes 218, may be employed.

Next, the detection hole 222 provided in the sealing portion 210b and rotation detection of the wafer W by a pressure gauge 223 will be described.

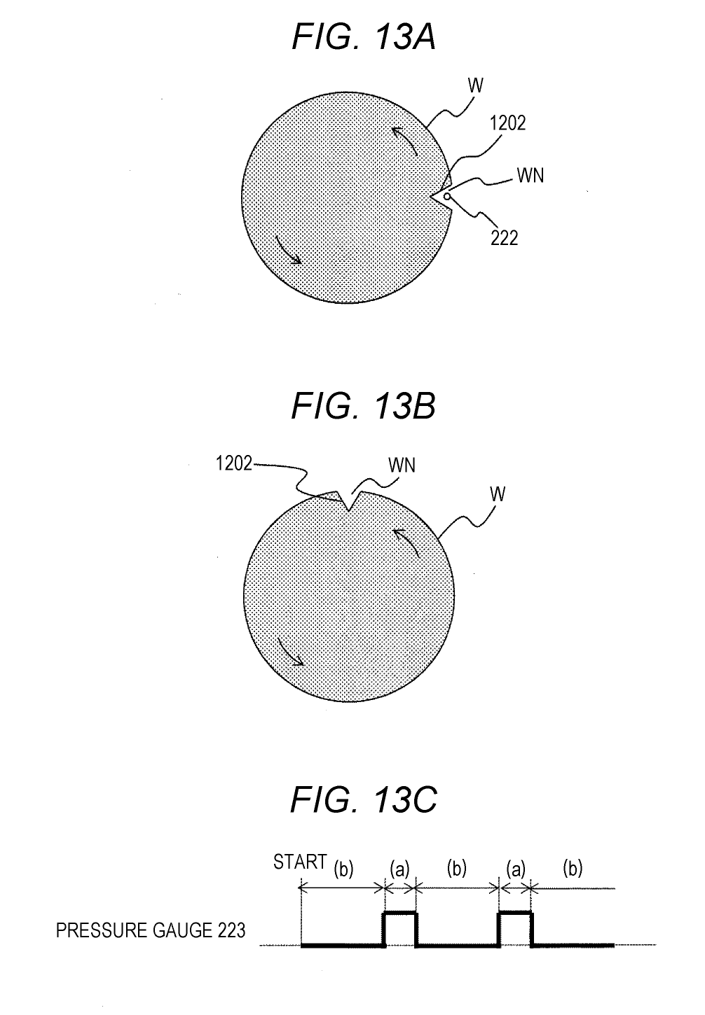

The pressure gauge 223 branching from and connected to the exhaust line 219 of the detection hole 222 is provided on the exhaust line 219. Change of the pressure detected by the pressure gauge 223 according to the rotation of the wafer W in a state where the wafer W is held above the sample stage 101d in a noncontact manner in the processing chamber 33 is illustrated in FIG. 13C.

FIGS. 13A and 13B illustrate a notch position of the wafer W at a specific angle position around the center of the rotated wafer W, and FIG. 13C illustrates change of the pressure detected from an output signal from the pressure gauge 223 over time in the state where the wafer W is rotated.

As illustrated in FIG. 13A, while a notch portion 1202 of the wafer W exists above the opening of the upper end portion of the detection hole 222, the wafer W that covers the opening of the upper end of the detection hole 222 does not exist above the opening, which is so-called an open state. Meanwhile, as illustrated in FIG. 13B, in a state where the notch portion 1202 of the rotated wafer W passes above the opening of the detection hole 222, the space above the opening is covered with the wafer W with the gap.

In this way, an open period in which the notch portion 1202 passes above the opening of the upper end portion of the detection hole 222 in the upper surface of the sealing portion 210 and the wafer W does not exist periodically occurs, according to the periodic movement of the angle position of the notch portion 1202 in the peripheral direction, which is associated with the rotation of the wafer W. In such a configuration, the processing chamber 33 is decompressed to have predetermined pressure, for example, 10 Pa, and the pressure is maintained, and the interior of the detection hole 222 and the exhaust line 219 communicate with the vacuum pump 221 in operation, and have lower pressure than the pressure inside the processing chamber 33. For example, in a case where the processing chamber 33 is decompressed to have 1 Pa or less, a large amount of gas flows into the detection hole 222 from the processing chamber 33 and through the gap between the wafer W and the sealing portion 210 in the state of FIG. 13A. As a result, the pressure in the exhaust line 219 is increased.

Meanwhile, in the state of FIG. 13B, the opening in the upper end portion of the detection hole 222 is covered with the wafer W, and flowing of the gas in the processing chamber 33 into the detection hole 222 becomes a smaller amount than the case of FIG. 13A. Regarding the amount of flowing of the gas into the detection hole 222 and a value of the internal pressure, two states are roughly periodically repeated, according to the periodic rotation of the wafer W, as illustrated in FIG. 13C.

That is, in a period in which the opening in the upper end portion of the detection hole 222 overlaps with an area and exists in the area, the area being downwardly projected from the notch portion 1202 of the wafer W, as viewed from above the wafer W, like FIG. 13A, the pressure detected from the signal output by the pressure gauge 223 arranged in the place communicating with the exhaust line 219 becomes a higher pulse value than a value detected in the period of FIG. 13B. By counting the number of times of the pulse value per unit time, the number of rotation (the number of rotation speed) per unit time of the wafer W can be calculated.

In the present embodiment, the output from the pressure gauge 223 illustrated in FIG. 10 is transmitted to a rotation speed controller 224 electrically connected with the pressure gauge 223 as a signal of a voltage or the like. The rotation speed controller 224 calculates the number of rotations of the wafer W on the basis of the signal of the pressure gauge 223, which is received by a calculator arranged therein, and algorithm of software read from a storage device such as a ROM or a hard disk, compares the calculated number of rotations and a desired value of the number of rotations as data stored in the storage device in advance.

When the rotation speed controller 224 determines that the calculated number of rotations is lower than the desired value, the rotation speed controller 224 sends a command signal to a flow rate control valve 206 of the heat transfer gas 205, which is arranged on the heat transfer gas supply passage 204, to increase the degree of opening to increase the supply amount of the heat transfer gas 205. The supply amount of the heat transfer gas 205 to the gap between the wafer W and the electrostatic absorbing layer 203 is increased, and as a result, external force acting on and rotating the wafer W is increased, and the number of rotations of the wafer W is increased.

Meanwhile, when the calculated number of rotations of the wafer W is determined to be higher than the desired value, the degree of opening of the flow rate control valve 206 of the heat transfer gas 205 is decreased in response to the command signal from the rotation speed controller 224, and the supply amount of the heat transfer gas 205 is decreased. Accordingly, the number of rotations of the wafer W is decreased.

In the present embodiment, the number of rotations of the wafer W detected as described above is fed back and the supply of the heat transfer gas 205 is regulated, whereby the number of rotations of the wafer W is regulated to fall within a desired range. In the present embodiment, the exhaust groove 217 or the plurality of exhaust holes 218 arranged to surround the center-side portion of the electrostatic absorbing layer 203 in a ring manner, and having the openings in the upper surface of the sealing portion 210, are arranged on a center portion side with respect to the opening of the detection hole 222 that detects that the notch portion 1202 is positioned or passes above the hole.

The heat transfer gas 205 supplied between the central portion of the electrostatic absorbing layer 203 and the wafer W is exhausted through the exhaust groove 217 or the plurality of exhaust holes 218, whereby the flow rate of the heat transfer gas 205 from the central portion to the interior of the processing chamber 33 on the outer periphery side of the wafer W is decreased, and the position shift of the wafer W arising in the horizontal direction by repulsive force of the heat transfer gas 205 flowing out through the notch portion 1202, or the magnitude of the position shift exceeding a permissible range are suppressed. Further, the detection hole 222 communicates with the vacuum pump 221 and the gas is exhausted, and thus the pressure in the processing chamber 33 >the pressure in the detection hole 222. The flow rate of the gas from the processing chamber 33 or through the gap of the sealing portion 210 in the open period in which the notch portion 1202 passes above the opening of the detection hole 222 is made larger than that in the period in which the opening is covered with the wafer W, whereby the passage of the notch portion 1202 and the number of times of the passage by the rotation of the wafer W can be more clearly detected.

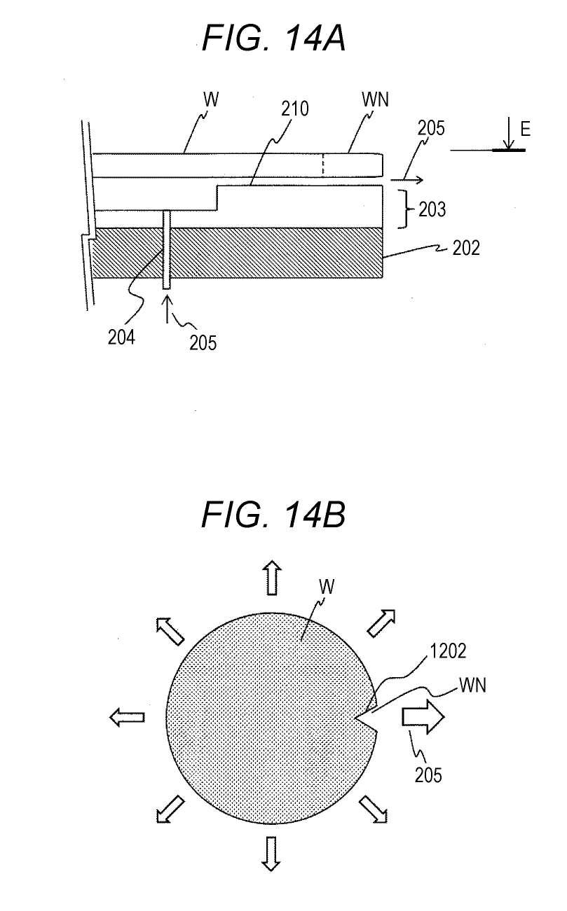

Note that FIGS. 14A and 14B illustrate a comparative example not including the exhaust paths of the heat transfer gas, which is included in the third embodiment. A sample stage 101e illustrated in FIG. 14A does not include the exhaust groove 217, the exhaust hole 218, and the detection hole 222 illustrated in FIG. 10 in the sealing portion 210 of the electrostatic absorbing layer 203. An opening communicating with the heat transfer gas supply passage 204 is arranged in the upper surface of the electrostatic absorbing layer 203 on a center side of the sealing portion 210, and the heat transfer gas 205 is supplied to the gap between the electrostatic absorbing layer 203 and the wafer W through the opening. A part of the supplied heat transfer gas 205 is diffused in the space of the gap between the back surface of the wafer W and the upper surface of the electrostatic absorbing layer 203 and surrounded by the sealing portion 210, and a remaining part of the heat transfer gas 205 passes through the gap between the sealing portion 210 and the wafer W and radially flows out from the center of the wafer W toward the interior of the processing chamber 33 on the outer periphery side of the wafer W.

In distribution of the amount of exhaust of the heat transfer gas 205 in the peripheral direction, the amount of exhaust is largest in a position WN that is the notch portion of the wafer W. The sealing portion 210 is provided in the outer periphery-side portion of the electrostatic absorbing layer 203, and the height of the gap between the wafer W and the sealing portion 210 is made smaller than that of the center-side portion of the electrostatic absorbing layer 203. Therefore, easy flowout of the heat transfer gas 205 from the center-side portion to the processing chamber 33 on the outer periphery side can be prevented. In this configuration, in the space above the sealing portion 210, in the position WN where the notch portion 1202 of the wafer W is positioned, so-called an open portion not covered with the outer peripheral edge of the wafer W exists, and therefore, the gap between the center-side portion of the electrostatic absorbing layer 203 by the sealing portion 210 and the processing chamber 33 on the outer periphery side is made small, and the distance to disturb (seal) circulation of the heat transfer gas 205 becomes short.

Therefore, the amount of flowout of the heat transfer gas 205 becomes locally larger in the position WN than other places of the outer peripheral edge of the wafer W, and the amount of flowout becomes nonuniform or deviation becomes large in the peripheral direction. If this deviation of the amount of flowout becomes large, the wafer W is made eccentric in a direction opposite to the direction going from the center to the position WN, and variation of the plasma in the in-plane direction of the upper surface of the wafer W, and of the dimension of the shape after processing as a result of the processing may become large.

Therefore, the opening of the exhaust groove 217 or the exhaust hole 218, which is arranged in the upper surface of the sealing portion 210, of the exhaust path of the heat transfer gas provided in the third embodiment, is arranged to be positioned on the center side with respect to a center-side end portion of the notch portion 1202 in the radial direction of the wafer W, in a state where the wafer W is held above the electrostatic absorbing layer 203 in a noncontact manner. Further, the opening in the upper end of the detection hole 222 in the upper surface of the sealing portion 210 is arranged on the outer periphery side with respect to the center-side end portion of the notch portion 1202 of the wafer W, and on the center side with respect to the outer periphery end of the wafer W, in the radial direction of the rotated wafer W.

### Fourth Embodiment

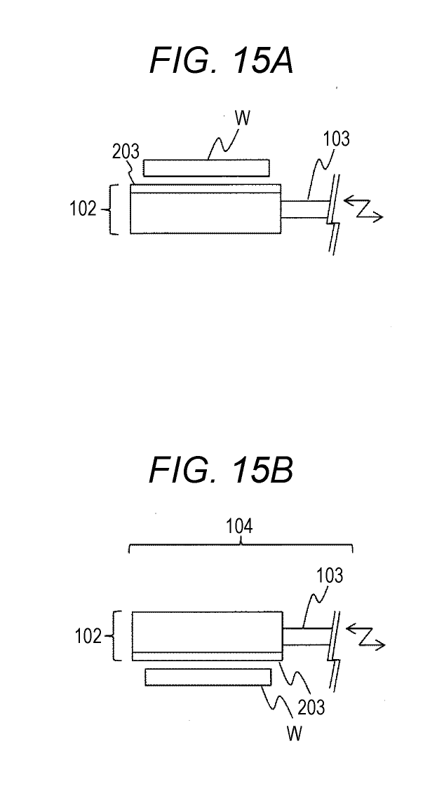

An example in which the configuration to float and hold the wafer above the sample stage in a noncontact manner, which has been described in the above embodiments, is applied to conveyance of a wafer will be described using FIGS. 15A and 15B to 18A and 18B. In the present example, the sample stage 101 or 1001 of the embodiments described so far is applied to a portion that holds a wafer, of a structural body that stretches an arm on which the wafer is placed, such as a robot arm in a conveying direction, and conveys the wafer.

Note that, in the sample stages 101 and 1001, the high-frequency power source 21 is electrically connected to the electrode block 202, the refrigerant flow channel 11 is arranged in the electrode block 202, and the temperature control unit 26 is connected to the electrode block 202. However, in a sample stage of a sample holder 102 for holding a wafer in this example, no high-frequency power source is connected and no refrigerant flow channel 11 is provided. The sample holder 102 can have the configuration of the sample stage 101 of the embodiment illustrated in FIGS. 2A and 2B in a case where rotation of the wafer during conveyance is not necessary, and can have the configuration of the sample stage 101 illustrated in FIGS. 8A and 8B and 9A and 9B, or of the sample stage 1001 illustrated in FIG. 10 in a case where rotation is necessary.

FIGS. 15A and 15B are side views schematically illustrating an outline of a configuration of a sample holder of a sample conveyor according to an embodiment of the present invention. FIG. 15A illustrates a sample conveyor of the present embodiment, which conveys the wafer W in a state of floating and holding the wafer W in a noncontact manner with a gap above an upper surface of the sample holder 102.

The sample holder 102 that conveys the wafer W of FIGS. 15A and 15B includes a sample stage arranged in a tip end of a conveyance arm 103 that is stretched in a desired direction. The sample stage includes an electrode block 202 made of metal and having a cylindrical shape, and an electrostatic absorbing layer 203 arranged on an upper surface of the electrode block 202. In the present example, electrostatic absorbing force that is formed by direct current power supplied to a film-like electrode (not illustrated) arranged in the electrostatic absorbing layer 203 and attracts the wafer W toward the electrostatic absorbing layer 203, and force to separate the wafer W by the gas supplied between the wafer W and the electrostatic absorbing layer 203 are balanced, and the wafer W is held above the electrostatic absorbing layer 203 in a noncontact manner and is conveyed.

Further, according to the configuration of the present example, in a state where the sample holder 102 is made upside down and the electrostatic absorbing layer 203 of the sample holder 102 faces downward in the configuration of FIG. 15A, and the wafer W is separated from the surface and held in a noncontact manner, the conveyance arm 103 can be stretched to move the sample holder 102, and the wafer W can be conveyed. Such an example is illustrated in FIG. 15B.

In the present embodiment, in a case where the temperature of the wafer W is not regulated while the wafer W is conveyed and held on the sample holder 102, the gas supplied between the surface of the electrostatic absorbing layer 203 of the sample holder 102 and the wafer W may just generate floating force, and does not require high thermal conductivity. Therefore, the gas can be selected from a large number of types of gasses.

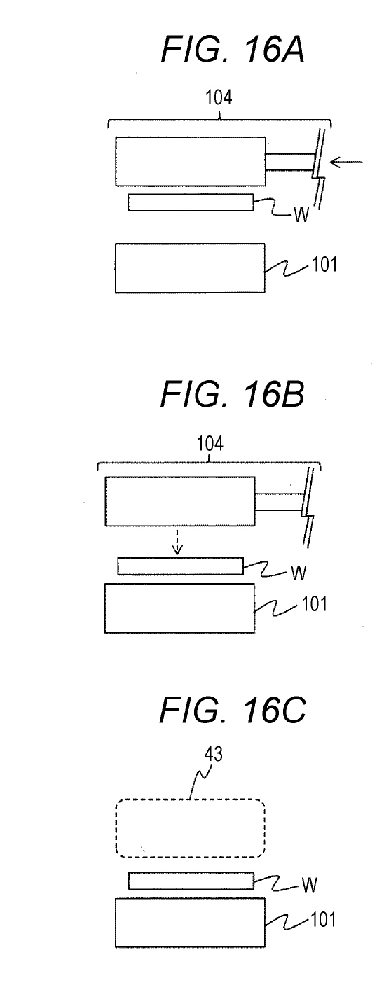

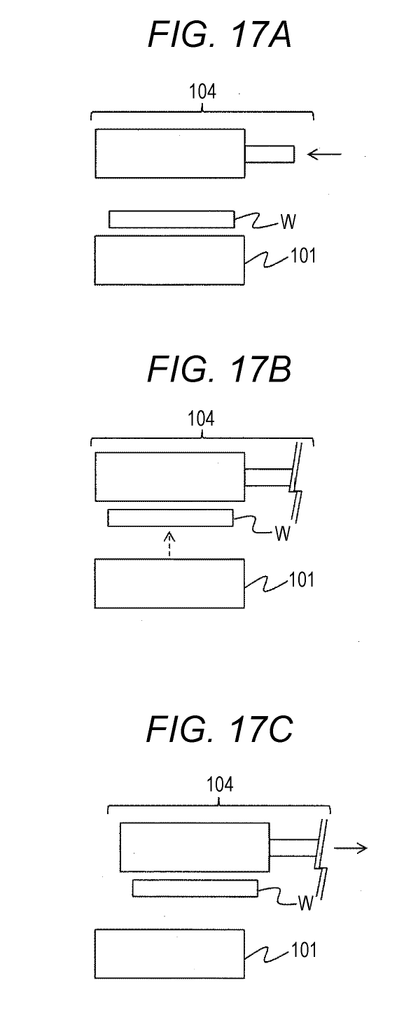

Further, the sample stage 101 or the sample stage 1001 of the above embodiment, and the sample holder 102 of the present example are combined, whereby the wafer W can be delivered between the sample conveyor such as the robot arm and the sample stage in a noncontact manner. Such an example will be described using FIGS. 16A to 16C and 17A to 17C.

FIGS. 16A to 16C and 17A to 17C are diagrams schematically illustrating an operation to convey the wafer between the sample stage that holds the wafer in a noncontact manner, of the embodiments illustrated in FIGS. 1 to 10, and the sample conveyor of the embodiment illustrated in FIGS. 15A and 15B. Note that, in these drawings, the sample stage 101 illustrated in FIGS. 2A and 2B to 9A and 9B is exemplarily illustrated. However, the configuration of the sample stage 1001 described in the embodiment of FIG. 10 may be applied.

FIG. 16A is a diagram illustrating a state in which the wafer W is held in noncontact manner above the surface of the sample conveyor 104 including the sample holder 102 and the arm 103 illustrated in FIGS. 15A and 15B, and is conveyed from an outside of a processing chamber 33 to above the electrostatic absorbing layer 203 of the sample stage 101. In this state, the position or the posture of the sample holder 102 is regulated in such a way that the upper surface of the electrostatic absorbing layer 203 of the sample stage 101, and the upper surface of the electrostatic absorbing layer 203 of the sample holder 102 or the surface of the wafer W (the lower surface in FIG. 16A) become parallel or nearly parallel.

In a state where the wafer W is held, as illustrated in FIG. 16B, in which an axis of the center of the wafer W in an up and down direction, the wafer W being held below the sample holder 102, and a central axis of the holding surface having a circular shape or an approximated shape that can be regarded as the circular shape covered with the electrostatic absorbing layer 203 of the sample stage 101, and on which the wafer is held, accord with each other or are in approximated positions regarded as according with each other, the electrostatic absorbing force generated for the wafer W by the sample conveyor 104 by the direct current power supplied to the film-like electrode in the electrostatic absorbing layer 203 of the sample holder 102 is gradually decreased, and force to separate the wafer W from above the surface of the sample holder 102, the force being formed by the gas supplied to the surface of the electrostatic absorbing layer 203 of the sample holder 102, is made relatively larger than the electrostatic absorbing force, and the wafer W is held in a noncontact state and moved toward the sample stage 101 (downward in FIG. 16B).

Note that, even during the movement of the wafer W, the heat transfer gas 205 is supplied above the upper surface of the electrostatic absorbing layer 203 of the sample stage 101 and the direct current power is supplied to the film-like electrode in the electrostatic absorbing layer 203, and the upward floating force to above the sample stage 101 by the heat transfer gas 205 and the downward electrostatic force are caused to act on the wafer W. These two forces are caused to act on the wafer W, which is moved from above, from the sample stage 101, to stop the movement and hold the wafer W in the position where the wafer W is floated above the upper surface of the sample stage 101 in a noncontact manner.

After that, the sample conveyor 104 is moved from the interior of the processing chamber 33 to an outside of the vacuum vessel 20 by stretching of the arm 103, a gate valve (not illustrated) air-tightly blocks up the gate to seal the processing chamber 33. In this state, as illustrated in FIG. 16C, the wafer W is floated above the sample stage 101 in a noncontact manner and is positioned in the up and down direction and the horizontal direction, etching processing of a film layer to be processed, of a film structure arranged on the upper surface of the wafer W, is performed using the plasma 43 formed using a processing gas supplied into the processing chamber 33.

FIG. 17A schematically illustrates a state in which, after termination of predetermined etching processing of the film layer to be processed of the upper surface of the wafer W illustrated in FIG. 16C is detected by a detector (not illustrated), the gate valve is open and the sample conveyor 104 stretches the arm 103 from the outside of the processing chamber 33, and the electrostatic absorbing layer 203 of the sample holder 102 is moved toward the lower sample stage 101 and above the wafer W held above the electrostatic absorbing layer 203 of the sample stage 101. Similarly to FIG. 16B, the arm 103 is stopped and held in a position where the axis of the center of the holding surface in an up and down direction, the holding surface having a circular shape or a shape equivalent to the circular shape, of the electrostatic absorbing layer 203 of the sample holder 102, where the wafer W is held, and the central axis of the holding surface of the wafer W, of the electrostatic absorbing layer 203 of the lower sample stage 101, or the wafer W above the holding surface, accord with each other or are in equivalent positions.

Next, as illustrated in FIG. 17B, the electrostatic absorbing force generated for the wafer W, of the sample stage 101, is gradually decreased, and the floating force of the wafer W by the heat transfer gas 205 supplied between the electrostatic absorbing layer 203 on the sample stage 101 and the wafer W is made relatively smaller than the electrostatic absorbing force. Therefore, the wafer W is moved and sent toward the sample holder 102 of the sample conveyor 104 above the sample stage 101 in FIG. 17B.

FIG. 17B is a diagram schematically illustrating a state in which the wafer W is moved to approach the sample holder 102 of the sample conveyor 104 from above the upper surface of the sample stage 101 while the noncontact state is maintained. Note that, in the sample holder 102 of the present embodiment, the wafer W moved from below is received and held at an upper position of a lower surface of the sample holder 102, the floating force formed by the heat transfer gas 205 supplied to the upper position of the lower surface of the sample holder 102, and the electrostatic force formed by the direct current power supplied to the film-like electrode arranged in the electrostatic absorbing layer 203 that configured the lower surface of the sample holder 102 are appropriately regulated, and the wafer W is held in a floated state below the lower surface of the sample conveyor 104 in a noncontact state.

In this way, the sample conveyor 104 is moved outside the processing chamber 33 in a state of holding the wafer W, the wafer W is carried out from the processing chamber 33. FIG. 17C is a diagram schematically illustrating a state in which the arm 103 of the sample conveyor 104 is shrank and moved from above the sample stage 101 to the outside of the processing chamber 33.

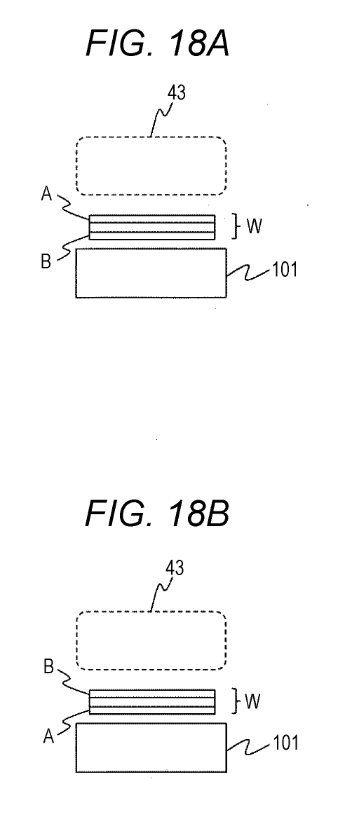

FIGS. 18A and 18B are diagrams schematically illustrating an example in which processing using plasma is performed for both a front surface and a back surface of the wafer W, using the sample conveyor 104 and the sample stage 101 described in FIGS. 15A and 15B to FIG. 17A to 17C. That is, the processing can be performed by using the configuration to hand over the wafer W between the sample stage 101 and the sample conveyor 104 described in FIGS. 15A and 15B to 17A to 17C, maintaining the state where the wafer W is held over the sample stage 101 and the sample conveyor 104 in a noncontact manner, holding both surfaces of the wafer W to face the processing chamber 33 side above the sample stage 101 in a noncontact manner, and exposing a film layer to be processed of a film structure arranged on each of the surfaces to plasma.

First, as illustrated in FIG. 18A, the wafer W is held above the upper surface of the sample stage 101, similarly to the embodiments illustrated in FIGS. 2A and 2B, 7, or 9A and 9B, in a noncontact state, and in a state where an A surface of the wafer W faces the space where the plasma is formed (the A surface faces upward in the processing chamber 33), and the plasma is formed in the processing chamber 33 and processing of a film structure formed in advance on the A surface is performed using the plasma. After that, the wafer W is handed over to the lower surface of the sample holder 102 of the sample conveyor 104 illustrated in FIGS. 15A and 15B to 17A to 17C, which has entered the processing chamber 33, with a gap from the lower surface, in a noncontact state. The sample conveyor 104 is left from the processing chamber 33 and carried outside the processing chamber 33.

After that, the wafer W is made upside down (not illustrated), the wafer W is again held in a noncontact manner in a state where a B surface faces the lower surface of the sample holder 102 of the sample conveyor 104 with a gap from the lower surface, is carried into the processing chamber 33, and is handed over to above the upper surface of the sample stage 101 in a noncontact state. Then, in a state where the wafer W is held such that the B surface faces the space where the plasma is formed (the B surface faces upward in the processing chamber 33), the plasma is formed in the processing chamber 33, as illustrated in FIG. 18B, and processing of a film structure formed in advance on the B surface is performed using the plasma.

In the above configuration, while the film structure of the upper surface of the wafer W, the upper surface facing the plasma, is processed by the plasma, the lower surface of the wafer W is held above the upper surface of the sample stage 101 in a noncontact state. Therefore, the shape of the film structure of the surface, which has been formed by the processing previously performed, coming in contact with the sample stage 101 and being changed, and thus the yield being decreased and the surface being contaminated, during the processing performed later, can be suppressed. In this way, the processing by plasma can be performed for the upper and lower two surfaces of the wafer W while suppressing the contamination of the surface of the wafer W and the decrease in the yield of the processing.

Note that, as means to make the wafer W upside down outside the processing chamber 33, the wafer W is accommodated in a stocker that can accommodate the wafers W after the processing of the A surface of the wafer W is terminated, and the stocker is inverted and installed, then the wafer W is held by the sample conveyor 104 in a noncontact manner again and may be taken out from the stocker. In this case, the stoker desirably has a structure that holds only a vicinity of an outer periphery of the wafer.

The present invention is not limited to the above-described embodiments, and can be also used in other apparatuses that require fine wafer temperature management while suppressing occurrence of foreign substances. For example, the present invention is useful for an asking apparatus, a sputtering apparatus, an ion implantation apparatus, or the like, which performs processing while heating the wafer to a high temperature.

What is claimed is:

1. A plasma processing apparatus comprising:
a processing chamber arranged in an interior of a vacuum vessel and in which plasma is formed;
a sample stage arranged in the processing chamber and having a wafer arranged on an upper surface, the wafer being to be processed using the plasma;
a temperature regulator arranged in an interior of the sample stage, and configured to regulate a temperature of the sample stage;
a film made of a dielectric that configures the upper surface of the sample stage, and including a film-like electrode inside the film;
a protruding portion arranged in an outer periphery-side area of an upper surface of the film made of a dielectric, and arranged to surround a center-side area of the upper surface in a ring manner;
an introducing port arranged in the center-side area of the upper surface of the film made of a dielectric, and configured to introduce a gas into a gap between the introducing port and the wafer in a state where the wafer is placed;
a power source configured to supply power that forms electrostatic force that absorbs the wafer arranged above the electrode in the film made of a dielectric; and
a controller configured to regulate the power from the power source and an amount of the gas through the introducing port to hold the wafer above the film made of a dielectric in noncontact manner.

2. The plasma processing apparatus according to claim 1,
wherein the controller is configured to control a temperature of the wafer using the temperature ragulater in a state where the wafer is held in a noncontact manner before or after the processing of the wafer is performed.

3. The plasma processing apparatus according to claim 1, wherein
the controller is configured to regulate the power from the power source and the amount of the gas through the introducing port to hold the wafer in a noncontact manner during the processing of the wafer.

4. The plasma processing apparatus according to claim 1, further comprising:
a ring made of a dielectric arranged on an outer periphery side of the film made of a dielectric in a ring manner, and the ring surrounding the wafer in a state where the wafer is arranged on the film made of a dielectric; and
a ring-like electrode arranged in a position where the ring-like electrode surrounds an outer periphery of the wafer in the ring, and to which a same polarity as a polarity of an outer peripheral edge of the wafer is provided.

5. The plasma processing apparatus according to claim 1, the controller is configured to hold the wafer in a noncontact manner while rotating the wafer.

6. The plasma processing apparatus according to claim 5, further comprising:
a groove arranged in an upper surface of the protruding portion in a peripheral direction of the upper surface of the dielectric film in an arc manner, and in which the gas flows.

7. A plasma processing method of arranging a wafer to be processed on a sample stage arranged in a processing chamber in an interior of a vacuum vessel and the sample stage including a temperature regulator inside the sample stage, and forming plasma in the processing chamber to process the wafer, the method comprising:
in a state where the wafer is placed on the sample stage, introducing a gas into a gap between an area and the wafer, the area being a center-side area of a film made of a dielectric that configures an upper surface of the sample stage, and the center-side area being inside a protruding portion arranged to surround the center-side area in a ring manner, and supplying power to a film-like electrode arranged in an interior of the film made of a dielectric, to form electrostatic force that absorbs the wafer; and
regulating the power from a power source and the amount of the gas through an introducing port, to regulate a temperature of the sample stage to a value within a predetermined range while holding the wafer above the film made of a dielectric in a noncontact manner.

8. The plasma processing method according to claim 7, comprising:
performing a process of changing a temperature of the wafer in a state where the wafer is held in a noncontact manner before or after the processing of the wafer is performed.

9. The plasma processing method according to claim 7, comprising:
performing the processing of the wafer in a state where the wafer is held in a noncontact manner.

10. The plasma processing method according to claim 7, comprising:
holding the wafer in a noncontact manner while rotating the wafer.

11. The plasma processing method according to claim 7, wherein
a plurality of film-like electrodes in which different polarities are provided to the electrodes in the film made of a dielectric are provided, and same polarities are provided to the plurality of electrodes during the processing of the wafer using the plasma and the different polarities are provided to the plurality of electrodes in a state where the plasma is not formed.

12. The plasma processing method according to claim 11, wherein
voltages having a same value are applied to the plurality of electrodes during the processing of the wafer using the plasma.

13. The plasma processing apparatus according to claim 5, further comprising:
a plurality of first exhaust ports arranged in the upper surface of the film made of a dielectric on an outer periphery side with respect to the introducing port, and through which the gas is exhausted;
a second exhaust port arranged in the upper surface of the film made of a dielectric, on an outer periphery side with respect to the first exhaust port, on a center side with respect to an outer peripheral edge of the placed and rotated wafer, and on an outer periphery side with respect to a center-side end portion of a notch portion of the wafer, and through which the gas in the processing chamber is exhausted; and
a pressure detector arranged to communicate with an exhaust path communicating with the second exhaust port, and configured to detect change of pressure in the exhaust path, wherein
the controller regulates supply of the gas, using the number of rotations of the wafer detected using an output from the pressure detector.

14. The plasma processing apparatus according to claim 13, wherein,
in a state where the wafer is held above the film made of a dielectric in a noncontact manner, pressure in the processing chamber is made lower than pressure in a gap between the film made of a dielectric and the wafer and inside the protruding portion, and is made higher than pressure in a gap between the protruding portion and the wafer.

15. The plasma processing apparatus according to claim 13, wherein
the plurality of first exhaust ports is arranged in positions having a predetermined distance from a center of the sample stage in a radial direction, and at equal angles around the center.

16. The plasma processing apparatus according to claim 15, comprising:
a groove portion having an opening in the upper surface of the protruding portion and arranged around the center in a ring manner, wherein
the plurality of first exhaust ports is arranged in an inner surface of the groove portion.
